(19) United States
(12) Patent Application Publication
(10) Pub. No.: US 2026/0293754 A1
(43) Pub. Date: Sep. 24, 2026

(54) SEMICONDUCTOR CHIP, AND SEMICONDUCTOR WAFER AND SEMICONDUCTOR PACKAGE INCLUDING THE SAME

(71) Applicant: SAMSUNG ELECTRONICS CO., LTD., Suwon-si (KR)

(72) Inventors: Hyoukyung CHO, Suwon-si (KR); Jaewha PARK, Suwon-si (KR); Chanmi LEE, Suwon-si (KR); Hojin LEE, Suwon-si (KR)

(73) Assignee: SAMSUNG ELECTRONICS CO., LTD., Suwon-si (KR)

(21) Appl. No.: 19/567,715

(22) Filed: Mar. 16, 2026

(30) Foreign Application Priority Data
Mar. 21, 2025 (KR) 10-2025-0036627

(51) Int. Cl. H10W 74/10; H10W 70/63; H10W 74/43

(52) U.S. Cl. CPC H10W 74/141; H10W 70/635; H10W 74/43

(57) ABSTRACT

A semiconductor chip includes a chip substrate including a first side and a second side opposing the first side in a vertical direction, a chip wiring structure positioned on the first side of the chip substrate and including a wiring area and dummy areas surrounding the wiring area, and a protective sidewall overlapping the dummy areas of the chip wiring structure in the vertical direction and being in contact with a side surface of the chip substrate and having an inner side surface coplanar with the side surface of the chip substrate, in which the chip wiring structure includes wiring patterns positioned in the wiring area and electrically connected to the chip substrate, and a wiring insulating layer positioned in the wiring areas and the dummy areas and surrounding the wiring patterns, and the wiring insulating layer of the chip wiring structure extends to an outside of the protective sidewall.

### CROSS-REFERENCE TO RELATED APPLICATION

This application is based on and claims priority under 35 U.S.C. § 119 to Korean Patent Application No. 10-2025-0036627, filed on Mar. 21, 2025, in the Korean Intellectual Property Office, the disclosure of which is incorporated by reference herein in its entirety.

### BACKGROUND

The inventive concept relates to a semiconductor chip, and a semiconductor wafer and a semiconductor package including the semiconductor chip.

In a semiconductor manufacturing process, a dicing process in which, after a plurality of semiconductor chips are formed on a wafer, the plurality of semiconductor chips are separated into individual chips, is performed. The quality of the dicing process is directly related to the yield of the semiconductor chips. Recently, chip sizes are continuously decreasing due to the trend toward high integration and miniaturization in the semiconductor industry, and dicing margins are also decreasing accordingly. In addition, dicing quality significantly affects the reliability and performance of a package, even in a packaging process to be performed after dicing. Thus, various methods and technologies for enhancing dicing quality have been studied.

### SUMMARY

The inventive concept provides a semiconductor chip in which deterioration of side surfaces of a semiconductor chip is suppressed during a dicing process, and a semiconductor wafer and a semiconductor package including the semiconductor chip.

However, the problems to be solved by the inventive concept are not limited to the problems mentioned above, and other problems not mentioned can be clearly understood by a person having ordinary skill in the relevant technical field from the description below.

According to an aspect of the inventive concept, there is provided a semiconductor chip including a chip substrate including a first side and a second side opposing the first side in a vertical direction, a chip wiring structure positioned on the first side of the chip substrate and including a wiring area and dummy areas surrounding the wiring area, and a protective sidewall overlapping the dummy areas of the chip wiring structure in the vertical direction and being in contact with a side surface of the chip substrate and having an inner side surface coplanar with the side surface of the chip substrate, in which the chip wiring structure includes wiring patterns positioned in the wiring area and electrically connected to the chip substrate, and a wiring insulating layer positioned in the wiring area and the dummy areas and surrounding the wiring patterns, and the wiring insulating layer of the chip wiring structure extends to the outside of the protective sidewall.

According to another aspect of the inventive concept, there is provided a semiconductor wafer including a wafer substrate including a first side and a second side opposing the first side and including a plurality of chip areas spaced apart from each other and dummy areas defining the plurality of chip areas, a wafer wiring structure positioned on the first side of the wafer substrate and including a plurality of wiring areas overlapping the plurality of chip areas of the wafer substrate in a vertical direction and dummy areas overlapping the dummy areas of the wafer substrate in the vertical direction, and a plurality of protective sidewalls penetrating the wafer substrate and positioned on the dummy areas of the wafer substrate, in which, in the plurality of protective sidewalls, the plurality of chip areas are respectively positioned in a space surrounded by each of the plurality of protective sidewalls.

According to another aspect of the inventive concept, there is provided a semiconductor package including a package substrate, a semiconductor chip including a chip substrate including a first side and a second side opposing the first side, a chip wiring structure positioned on the first side of the chip substrate and including a wiring area and dummy areas surrounding the wiring area, and a protective sidewall overlapping the dummy areas of the chip wiring structure in a vertical direction, being in contact with a side surface of the chip substrate and having an inner side surface coplanar with the side surface of the chip substrate, in which, in the semiconductor chip, the chip wiring structure is positioned on the package substrate, and a molding layer positioned on the package substrate and covering an outer side surface of the protective sidewall of the semiconductor chip, the outer side surface of the protective sidewall of the semiconductor chip includes a first outer side surface and a second outer side surface that are spaced apart from each other with the chip substrate therebetween, and a separation distance between the first outer side surface and the second outer side surface of the protective sidewall of the semiconductor chip is less than a width of the chip wiring structure.

According to another aspect of the inventive concept, there is provided a method of manufacturing a semiconductor chip, the method including attaching a wafer substrate to a first carrier substrate, the wafer substrate including a plurality of chip areas and dummy areas defining the plurality of chip areas and including a first side and a second side opposing the first side, forming a plurality of trenches penetrating the wafer substrate in the dummy areas of the wafer substrate, forming a plurality of protective sidewalls by filling an insulating material in the plurality of trenches, forming a wafer wiring structure on the first side of the wafer substrate to include a plurality of wiring areas and dummy areas defining the plurality of wiring areas, cutting a separation space between the plurality of protective sidewalls removing a portion of the wafer wiring structure, and removing the wafer substrate positioned on an outside of the plurality of protective sidewalls.

After the removing of the wafer substrate positioned on the outside of the plurality of protective sidewalls, a portion of the wafer wiring structure may remain in the outside of each of the plurality of protective sidewalls.

The plurality of trenches may have a horizontal width that decreases in a direction away from the first side of the wafer.

Each of the plurality of protective sidewalls may include a first side and a second side opposing the first side, and the first side of each of the plurality of protective sidewalls may be coplanar with the first side of the wafer substrate, and the second side of each of the plurality of protective sidewalls may be coplanar with the second side of the wafer substrate.

After the forming of the wafer wiring structure, forming the plurality of trenches and forming the plurality of protective sidewalls may be performed, and the plurality of trenches may penetrate the dummy areas of the wafer wiring structure.

The length of the plurality of protective sidewalls in the vertical direction may be equal to the sum of the length of the wafer wiring structure in the vertical direction and the length of the wafer substrate in the vertical direction.

The method may further include moving the wafer substrate to a second carrier substrate so that the second side of the wafer substrate is exposed, and forming a wafer bonding structure on the second side of the wafer substrate, the wafer bonding structure including a plurality of pattern areas and dummy areas defining the plurality of pattern areas, and the dummy areas of the wafer bonding structure may overlap the dummy areas of the wafer wiring structure in the vertical direction.

The wafer substrate may further include a through via positioned in the plurality of chip areas of the wafer substrate and penetrating the wafer substrate, and in the cutting of the separation space between the plurality of protective sidewalls, a portion of the dummy areas of the wafer bonding structure may be removed.

After the removing of the wafer substrate positioned on the outside of the plurality of protective sidewalls, a portion of the wafer bonding structure may remain in the outside of each of the plurality of protective sidewalls.

After the forming of the wafer wiring structure and the wafer bonding structure, forming of the plurality of trenches and forming of the plurality of protective sidewalls may be performed, and the plurality of trenches may penetrate the dummy areas of the wafer wiring structure and the dummy areas of the wafer bonding structure.

### BRIEF DESCRIPTION OF THE DRAWINGS

Embodiments will be more clearly understood from the following detailed description taken in conjunction with the accompanying drawings in which:

FIG. 1 is a perspective view schematically illustrating a semiconductor chip according to embodiments;

FIG. 2 is a plan view schematically illustrating a semiconductor chip according to embodiments;

FIG. 3 is a cross-sectional view schematically illustrating a semiconductor chip according to embodiments;

FIG. 4 is a cross-sectional view schematically illustrating a semiconductor chip according to embodiments;

FIG. 5 is a perspective view schematically illustrating a semiconductor chip according to embodiments;

FIG. 6 is a cross-sectional view schematically illustrating a semiconductor chip according to embodiments;

FIG. 7 is a cross-sectional view schematically illustrating a semiconductor chip according to embodiments;

FIG. 8 is a cross-sectional view schematically illustrating a semiconductor chip according to embodiments;

FIG. 9 is a cross-sectional view schematically illustrating a semiconductor chip according to embodiments;

FIG. 10 is a plan view schematically illustrating a semiconductor wafer according to embodiments;

FIG. 11 is a cross-sectional view schematically illustrating a portion of a semiconductor wafer according to embodiments;

FIG. 12 is a cross-sectional view schematically illustrating a portion of a semiconductor wafer according to embodiments;

FIG. 13 is a cross-sectional view schematically illustrating a portion of a semiconductor wafer according to embodiments;

FIG. 14 is a cross-sectional view schematically illustrating a portion of a semiconductor wafer according to embodiments;

FIG. 15 is a cross-sectional view schematically illustrating a portion of a semiconductor wafer according to embodiments;

FIG. 16 is a cross-sectional view schematically illustrating a portion of a semiconductor wafer according to embodiments;

FIG. 17 is a cross-sectional view schematically illustrating a semiconductor package according to embodiments;

FIG. 18 is a cross-sectional view schematically illustrating a semiconductor package according to embodiments;

FIGS. 19A, 19B, 19C, 19D, 19E, 19F, and 19G are cross-sectional views illustrating a method of manufacturing a semiconductor chip according to embodiments in a process sequence; and

FIGS. 20A, 20B, 20C, 20D, 20E, 20F, 20G, 20H, and 20I are cross-sectional views illustrating a method of manufacturing a semiconductor chip according to embodiments in a process sequence.

### DETAILED DESCRIPTION OF THE EMBODIMENTS

Embodiments of the inventive concept are provided to more completely explain the inventive concept to those skilled in the art to which the concept of the inventive concept belongs, and the following embodiments may be modified in various other forms, and the scope of the inventive concept is not limited to the following embodiments. Rather, these embodiments are provided so that this disclosure will be more faithful and complete, and will fully convey the spirit of the inventive concept to those skilled in the art.

In the present specification, spatially relative terms such as “top surface,” “bottom surface,” “upper part,” “lower part,” “top,” and “bottom” are used to easily explain the positional relationship of each component when viewed with respect to the direction illustrated in the drawings. Thus, the spatially relative terms indicating the positional relationship of each component may be understood differently when viewed from a different direction than that illustrated in the drawing.

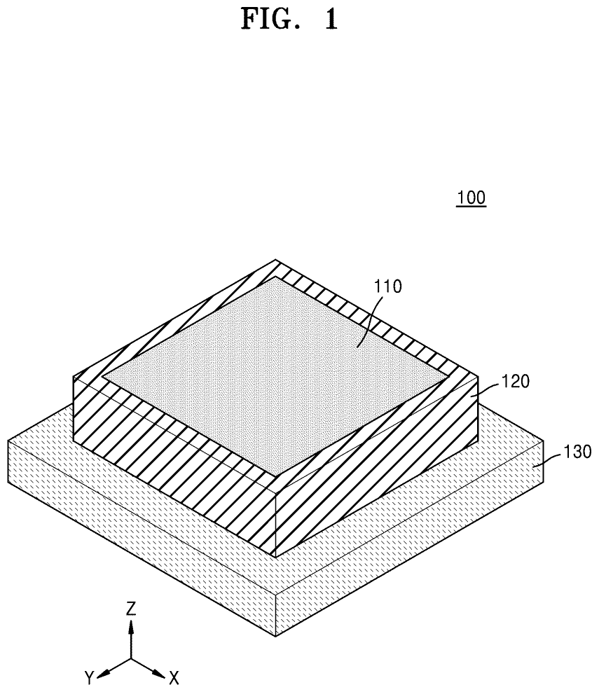

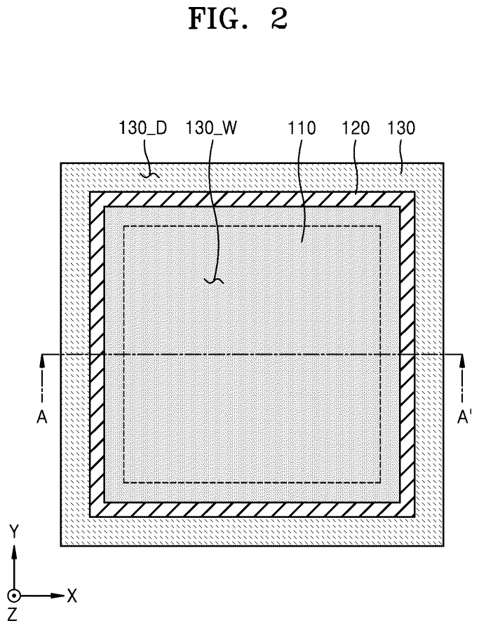

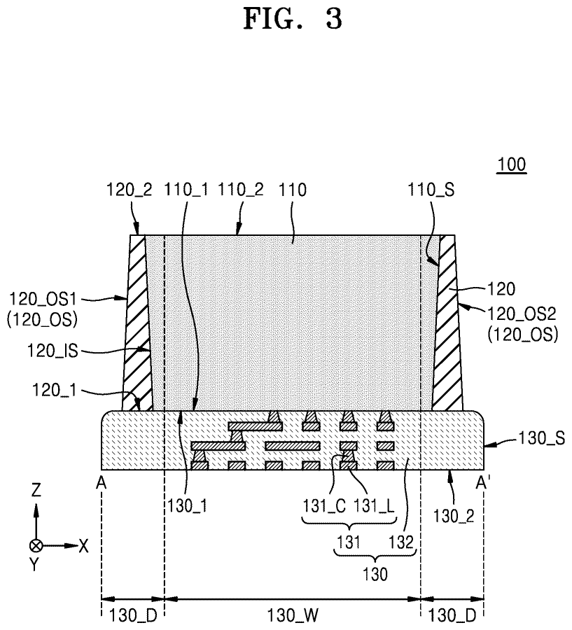

FIG. 1 is a perspective view schematically illustrating a semiconductor chip 100 according to embodiments. FIG. 2 is a plan view schematically illustrating the semiconductor chip 100 according to embodiments. FIG. 3 is a cross-sectional view schematically illustrating the semiconductor chip 100 according to embodiments. For example, FIG. 3 is a cross-sectional view of the semiconductor chip 100 of FIG. 2, taken along a line A-A′ of FIG. 2.

In the present specification, unless otherwise specifically defined, a direction parallel to the upper surface of a chip substrate 110 is defined as a first horizontal direction (X direction), a direction perpendicular to the upper surface of the chip substrate 110 is defined as a vertical direction (Z direction), and a direction perpendicular to the first horizontal direction (X direction) and the vertical direction (Z direction) is defined as a second horizontal direction (Y direction). The horizontal direction is defined as the direction that is a composite of the first horizontal direction (Y direction) and the second horizontal direction (X direction).

Referring to FIGS. 1 through 3, the semiconductor chip 100 may include the chip substrate 110, a chip wiring structure 130, and a protective sidewall 120.

The chip substrate 110 may include a first side 110_1 and a second side 110_2 opposite thereto. For example, a plurality of individual devices may be positioned on the first side 110_1 of the chip substrate 110. For example, the first side 110_1 of the chip substrate 110 may be referred to as a front side or an active side, and the second side 110_2 of the chip substrate 110 may be referred to as a back side or an inactive side.

The chip substrate 110 may include a semiconductor material, for example, silicon (Si) or germanium (Ge). The chip substrate 110 may include a compound semiconductor material such as silicon carbide (SiC), gallium arsenide (GaAs), indium arsenide (InAs), and indium phosphide (InP).

In some embodiments, the chip substrate 110 may include a front end of line (FEOL) structure. The FEOL structure of the chip substrate 110 may include the first side 110_1 of the chip substrate 110. For example, a plurality of individual devices and a transistor may be positioned within the FEOL structure of the chip substrate 110.

A semiconductor device including a variety of types of individual devices may be disposed on the first side 110_1 of the chip substrate 110. The plurality of individual devices of a second semiconductor substrate 211 may include various microelectronic devices, for example, a metal-oxide-semiconductor field effect transistor (MOSFET) such as a complementary metal-oxide-semiconductor (CMOS) transistor, system large scale integration (LSI), an image sensor such as a CMOS imaging sensor (CIS), a micro-electro-mechanical system (MEMS), an active device, a passive device, or the like

In some embodiments, the chip substrate 110 may include a memory cell. For example, the memory cell may be a nonvolatile memory cell such as flash memory, phase-change random access memory (PRAM), magnetoresistive random access memory (MRAM), ferroelectric random access memory (FeRAM) or resistive random access memory (RRAM). In some embodiments, the memory cell may be a volatile memory cell such as dynamic random access memory (DRAM) or static random access memory (SRAM).

The chip wiring structure 130 may be positioned on the first side 110_1 of the chip substrate 110. For example, the chip wiring structure 130 may be electrically connected to the FEOL structure of the chip substrate 110. For example, the chip wiring structure 130 may be referred to as a back end of line (BEOL) structure.

For example, the chip wiring structure 130 may include a first side 130_1 and a second side 130_2 opposite thereto. The first side 130_1 of the chip wiring structure 130 may be in contact with the first side 110_1 of the chip substrate 110. Chip connection terminals such as solder bumps, solder balls, or the like may be attached to the second side 130_2 of the chip wiring structure 130.

The chip wiring structure 130 may include wiring patterns 131 and a wiring insulating layer 132 that surrounds the wiring patterns 131. Each of the wiring patterns 131 may include a wiring line 131_L that extends in the horizontal direction, and a wiring contact 131_C that extends from the wiring line 131_L in the vertical direction (Z direction). The wiring patterns 131 may be electrically connected to the plurality of individual devices positioned on the first side 110_1 of the chip substrate 110. The wiring patterns 131 may include copper, nickel, stainless steel or beryllium copper.

The chip wiring structure 130 may include a wiring area 130_W and dummy areas 130_D that surround the wiring area 130_W. For example, the wiring area 130_W may be an area in which the wiring patterns 131 and the wiring insulating layer 132 are positioned. For example, the dummy areas 130_D of the chip wiring structure 130 may be areas in which the wiring patterns 131 are not positioned but only the wiring insulating layer 132 is positioned. That is, the wiring patterns 131 may be positioned only in the wiring area 130_W, and the wiring insulating layer 132 may be positioned in the wiring area 130_W and the dummy areas 130_D.

For example, the center area of the wiring structure 130 may be positioned in the wiring area 130_W, and the dummy areas 130_D may be positioned in the corner of the chip wiring structure 130. For example, in a plan view, the wiring area 130_W may have a square shape, and the dummy areas 130_D may have a square ring shape that surrounds the wiring area 130_W. For example, a side surface 130_S of the chip wiring structure 130 may be included in the dummy areas 130_D of the chip wiring structure 130, and the wiring area 130_W of the chip wiring structure 130 may be spaced apart from the side surface 130_S of the chip wiring structure 130.

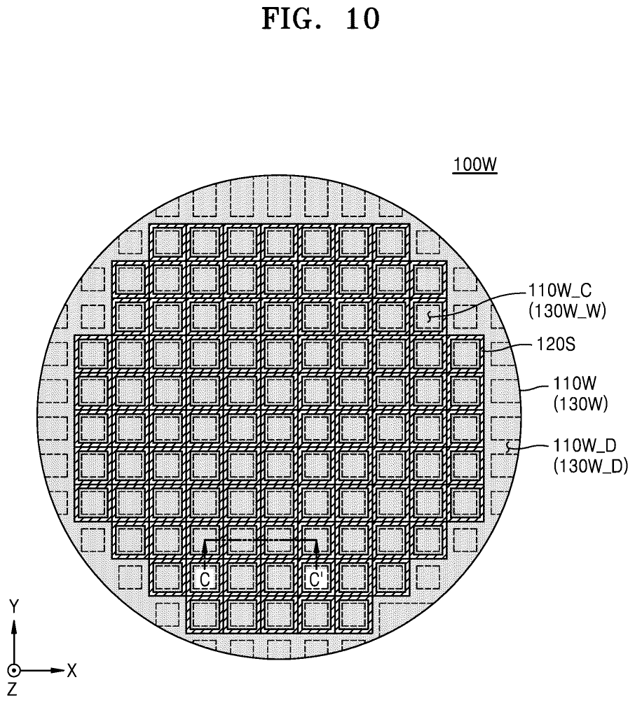

In some embodiments, the plurality of individual devices of the first side 110_1 of the chip substrate 110 may be positioned in the wiring area 130_W of the chip wiring structure 130. The dummy areas 130_D of the chip wiring structure 130 may be areas included in a scribe lane required in a dicing process of separating a semiconductor wafer (see 100W of FIG. 10) into a plurality of semiconductor chips. The plurality of individual devices may not be formed in an area of the first side 110_1 of the chip substrate 110 that overlaps the dummy areas 130_D of the chip wiring structure 130.

In some embodiments, the corner of the first side 130_1 of the chip wiring structure 130 may have a rounded shape. For example, the corner of the first side 130_1 of the chip wiring structure 130 may have a curvature. For example, the corner of the first side 130_1 of the chip wiring structure 130 may have a convexly rounded shape toward the outside.

The protective sidewall 120 may be positioned on the first side 130_1 of the chip wiring structure 130 and may be in contact with the side surface 110_S of the chip substrate 110. For example, the protective sidewall 120 may completely cover the side surface 110_S of the chip substrate 110. For example, an inner side surface 120_IS of the protective sidewall 120 may be coplanar with the side surface 110_S of the chip substrate 110.

In some embodiments, the side surface 110_S of the chip substrate 110 may not be exposed to the outside by the protective sidewall 120. An outer side surface 120_OS opposing the inner side surface 120_IS of the protective sidewall 120 may be exposed to the outside of the semiconductor chip 100.

The protective sidewall 120 and the plurality of individual devices of the first side 110_1 of the chip substrate 110 may be spaced apart from each other. For example, in order to suppress a shape in which the protective sidewall 120 interferes with the plurality of individual devices of the first side 110_1 of the chip substrate 110, the protective sidewall 120 and the plurality of individual devices of the first side 110_1 of the chip substrate 110 may be spaced apart from each other. For example, a separation space between the protective sidewall 120 and the plurality of individual devices of the first side 110_1 of the chip substrate 110 may overlap the dummy areas 130_D of the chip wiring structure 130 in the vertical direction (Z direction).

In some embodiments, in a plan view, the chip substrate 110 may have a square shape, and the protective sidewall 120 may have a square ring shape that surrounds the chip substrate 110. For example, the chip substrate 110 may be positioned in an internal space defined by the inner side surface 120_IS of the protective sidewall 120.

In some embodiments, the protective sidewall 120 may having a horizontal width that varies in a direction away from the chip wiring structure 130. For example, the protective sidewall 120 may have a horizontal width that decreases in a direction away from the chip wiring structure 130. However, embodiments are not limited thereto, and the protective sidewall 120 may have a horizontal width that increases in a direction away from the chip wiring structure 130. In the present specification, the horizontal width of the protective sidewall 120 means the length between the inner side surface 120_IS and the outer side surface 120_OS of the protective sidewall 120.

The protective sidewall 120 may be positioned in the dummy areas 130_D of the chip wiring structure 130. For example, the protective sidewall 120 may overlap the dummy areas 130_D of the chip wiring structure 130 in the vertical direction (Z direction). The wiring insulating layer 132 of the chip wiring structure 130 may extend to the outside of the protective sidewall 120. For example, the chip wiring structure 130 may further extend to the outside of the protective sidewall 120 in the horizontal direction.

In a plan view, the side surface 130_S of the chip wiring structure 130 may be positioned on the outside of the outer side surface 120_OS of the protective sidewall 120. For example, in a plan view, the side surface 130_S of the chip wiring structure 130 and the outer side surface 120_OS of the protective sidewall 120 may be spaced apart from each other. For example, there may be a step height between the side surface 130_S of the chip wiring structure 130 and the outer surface 120_OS of the protective side wall 120. For example, the outer side surface 120_OS of the protective sidewall 120 may be positioned on the first side 130_1 of the chip wiring structure 130.

The outer side surface 120_OS of the protective sidewall 120 may include a first outer side surface 120_OS1 and a second outer side surface 120_OS2. For example, the first outer side surface 120_OS1 and the second outer side surface 120_OS2 may be spaced apart from each other with the chip substrate 110 therebetween. For example, the first outer side surface 120_OS1 and the second outer side surface 120_OS2 may be two opposite outer side surfaces of the outer side surfaces 120_OS. The distance between the first outer side surface 120_OS1 and the second outer side surface 120_OS2 may be less than the width of the chip wiring structure 130.

In some embodiments, the protective sidewall 120 may include a first side 120_1 and a second side 120_2 adjacent to the inner side surface 120_IS and the outer side surface 120_OS. For example, the first side 120_1 of the protective sidewall 120 and the second side 120_2 of the protective sidewall 120 may be spaced apart from each other in the vertical direction (Z direction). The first side 120_1 of the protective sidewall 120 may be coplanar with the first side 110_1 of the chip substrate 110 and may be in contact with the first side 130_1 of the chip wiring structure 130. The second side 120_2 of the protective sidewall 120 may be coplanar with the second side 110_2 of the chip substrate 110.

In some embodiments, the vertical (Z-direction) length of the protective sidewall 120 may be equal to the vertical (Z-direction) length of the chip substrate 110. For example, a separation distance between the first side 120_1 of the protective sidewall 120 and the second side 120_2 of the protective sidewall 120 in the vertical direction (Z direction) may be equal to a separation distance between the first side 110_1 of the chip substrate 110 and the second side 110_2 of the chip substrate 110 in the vertical direction (Z direction).

In some embodiments, the protective sidewall 120 may include an insulating material such as silicon oxide, silicon nitride, or the like. In some embodiments, the protective sidewall 120 may include an epoxy resin or a polyimide resin.

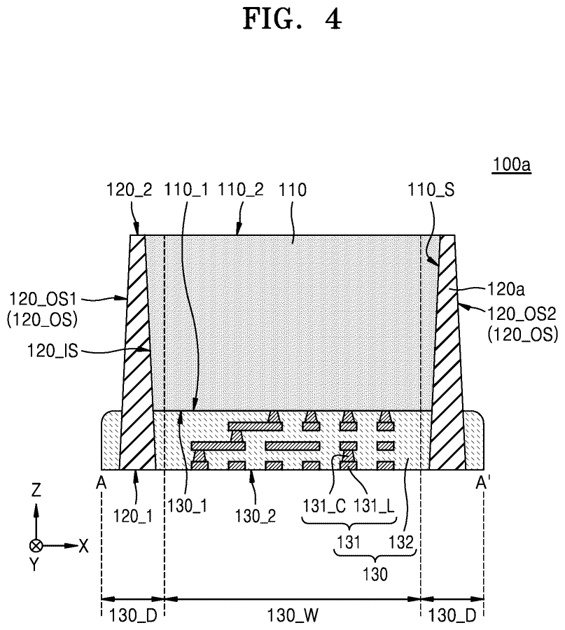

FIG. 4 is a cross-sectional view schematically illustrating a semiconductor chip 100a according to embodiments. For example, FIG. 4 is a cross-sectional view of the semiconductor chip 100a, taken along a line A-A′ of FIG. 2.

Most of the components and materials forming the semiconductor chip 100a described below are substantially the same as or similar to those described above with reference to FIG. 3. Thus, for convenience of explanation, the differences between the semiconductor chip 100a of FIG. 4 and the semiconductor chip 100 of FIG. 3 described above will be described.

Referring to FIG. 4, the semiconductor chip 100a may include the chip substrate 110, the chip wiring structure 130, and a protective sidewall 120a. The protective sidewall 120a of the semiconductor chip 100a of FIG. 4 is different from the semiconductor chip 100 of FIG. 3 in that the protective sidewall 120a of the semiconductor chip 100a of FIG. 4 penetrates the chip wiring structure 130.

A second side 120_2 of the protective sidewall 120a may be coplanar with a second side 110_2 of the chip structure 110. The protective sidewall 120a may penetrate the chip wiring structure 130 so that the first side 120_1 of the protective sidewall 120a may be coplanar with the second side 130_2 of the chip wiring structure 130. For example, the length of the protective sidewall 120a in the vertical direction (Z direction) may be equal to the sum of the length of the chip wiring structure 130 in the vertical direction (Z direction) and the length of the chip wiring structure 130 in the vertical direction (Z direction).

The protective sidewall 120a may penetrate the dummy areas 130_D of the chip wiring structure 130. For example, the protective sidewall 120a may be spaced apart from the wiring area 130_W of the chip wiring structure 130. For example, the protective sidewall 120a may be spaced apart from the wiring patterns 131 of the chip wiring structure 130 to secure a margin distance.

The horizontal width of the protective sidewall 120a may be decreased in a direction away from the second side 130_2 of the chip wiring structure 130. A portion of the outer side surface 120_OS of the protective sidewall 120a may be covered by the wiring insulating layer 132 of the chip wiring structure 130. For example, the wiring insulating layer 132 may be positioned on the outside of the portion of the outer side surface 120_OS of the protective sidewall 120a.

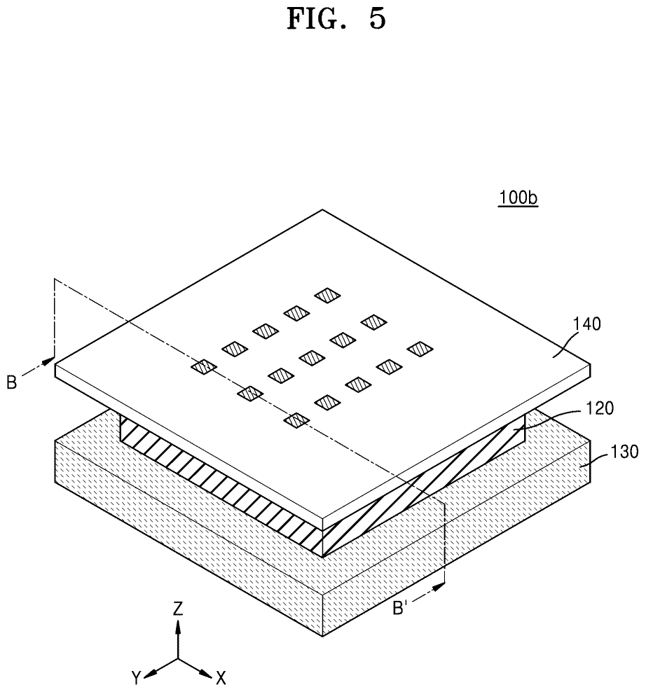

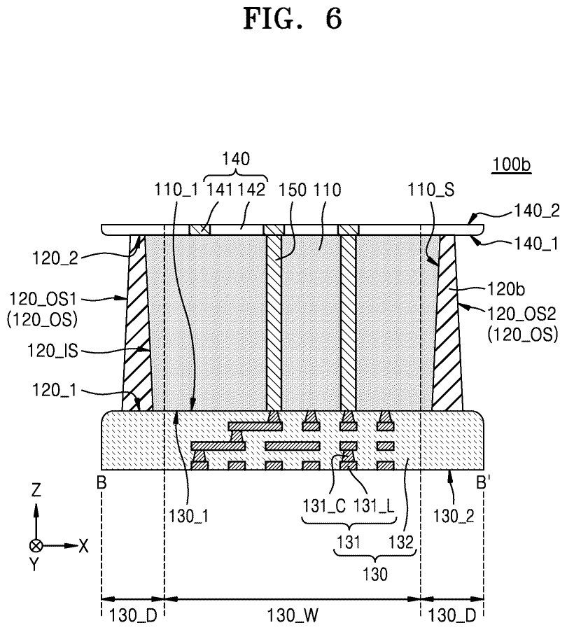

FIG. 5 is a perspective view schematically illustrating a semiconductor chip 100b according to embodiments. FIG. 6 is a cross-sectional view schematically illustrating the semiconductor chip 100b according to embodiments. For example, FIG. 6 is a cross-sectional view of the semiconductor chip 100b of FIG. 5, taken along a line B-B′ of FIG. 5.

Most of the components and materials forming the semiconductor chip 100b described below are substantially the same as or similar to those described above with reference to FIG. 3. Thus, for convenience of explanation, the difference between the semiconductor chip 100b of FIG. 5 and the semiconductor chip 100 of FIG. 3 described above will be explained.

Referring to FIGS. 5 and 6, the semiconductor chip 100b may include the chip substrate 110, the chip wiring structure 130, a protective sidewall 120b, a through via 150, and a bonding structure 140. The semiconductor chip 100b of FIG. 6 is different from the semiconductor chip 100 of FIG. 3 in that the semiconductor chip 100b of FIG. 6 further includes the through via 150 and the bonding structure 140.

The through via 150 may penetrate the chip substrate 110. The through via 150 may extend from the first side 110_1 of the chip substrate 110 to the second side 110_2 of the chip substrate 110 in the vertical direction (Z direction). The through via 150 may be electrically connected to the chip wiring structure 130. The through via 150 may be electrically connected to the wiring patterns 131 of the chip wiring structure 130. The through via 150 may overlap the wiring area 130_W of the chip wiring structure 130 in the vertical direction (Z direction). In some embodiments, the through via 150 may include copper, nickel, stainless steel or beryllium copper.

The bonding structure 140 may be positioned on the chip substrate 110 and the protective sidewall 120b. The bonding structure 140 may be positioned on the second side 110_2 of the chip substrate 110 and the second side 120_2 of the protective sidewall 120b. The bonding structure 140 may be disposed on a back surface of the chip substrate 110 and may be referred to as a back structure. The bonding structure 140 may be spaced apart from the chip wiring structure 130 with the chip substrate 110 and the protective sidewall 120b therebetween.

The bonding structure 140 may include a first side 140_1 and a second side 140_2 opposite thereto. The first side 140_1 of the bonding structure 140 may be a side being in contact with the second side 110_2 of the chip substrate 110, and the second side 140_2 of the bonding structure 140 may be a side that forms an outer surface of the semiconductor chip 100b.

The bonding structure 140 may include bonding patterns 141 and a bonding insulating layer 142 that surrounds the bonding patterns 141. The bonding patterns 141 may include a conductive material, and the bonding insulating layer 142 may include an insulating material. The bonding patterns 141 may be electrically connected to the through via 150. The bonding structure 140 and the chip wiring structure 130 may be electrically connected to each other through the through via 150.

In some embodiments, the bonding patterns 141 may include bonding lines (e.g., bonding pads) that form a single layer and extend in the horizontal direction. In some embodiments, the bonding patterns 141 may include a plurality of bonding lines that form a single layer and have different vertical levels, and a bonding via that extends from the plurality of bonding lines in the vertical direction.

In some embodiments, the length of the bonding structure 140 in the vertical direction (Z direction) may be less than the length of the chip wiring structure 130 in the vertical direction (Z direction). For example, the length of the bonding structure 140 in the vertical direction (Z direction) may be about 3 μm to about 8 μm, and the length of the chip wiring structure 130 in the vertical direction (Z direction) may be about 11 μm to about 17 μm.

In some embodiments, the bonding structure 140 may include a pattern area and dummy areas that surround the pattern area. For example, the pattern area of the bonding structure 140 may overlap the wiring area 130_W of the chip wiring structure 130 in the vertical direction (Z direction), and the dummy areas of the bonding structure 140 may overlap the dummy areas 130_D of the chip wiring structure 130 in the vertical direction (Z direction).

In some embodiments, the pattern area of the bonding structure 140 may be positioned in the center of the bonding structure 140, and the dummy areas of the bonding structure 140 may be positioned at the corner of the bonding structure 140. In a plan view, the pattern area of the bonding structure 140 may have a square shape, and the dummy areas of the bonding structure 140 may have square ring shapes.

The bonding patterns 141 and the bonding insulating layer 142 may be positioned in the pattern area of the bonding structure 140, the bonding insulating layer 142 may be positioned in the dummy areas of the bonding structure 140, and the bonding patterns 141 may not be positioned in the dummy areas of the bonding structure 140. The bonding patterns 141 may be spaced apart from the dummy areas of the bonding structure 140 in the horizontal direction.

The through via 150 may overlap the pattern area of the bonding structure 140 and the wiring area 130_W of the chip wiring structure 130 in the vertical direction (Z direction). For example, the through via 150 may be electrically connected to the wiring patterns 131 of the chip wiring structure 130 and the bonding patterns 141 of the bonding structure 140.

The protective sidewall 120b may be positioned between the chip wiring structure 130 and the bonding structure 140. For example, the bonding insulating layer 142 of the bonding structure 140 may extend to the outside of the protective sidewall 120b.

The protective sidewall 120b may overlap the dummy areas of the bonding structure 140 in the vertical direction (Z direction). In a plan view, the outer side surface 120_OS of the protective sidewall 120b may be positioned under the bonding structure 140 and may be covered by the bonding structure 140. A separation distance between the first outer surface 120_OS1 and the second outer surface 120_OS2 of the protective sidewall 120b may be less than the width of the bonding structure 140.

The second side 120_2 of the protective sidewall 120b may be in contact with the first side 140_1 of the bonding structure 140 and may be coplanar with the first side 140_1 of the bonding structure 140. The first side 120_1 of the protective sidewall 120b may be in contact with the first side 130_1 of the wiring structure 130 and may be coplanar with the first side 130_1 of the chip wiring structure 130.

In some embodiments, the bonding structure 140 may have a rounded shape at the corner of the first side 140_1. For example, the bonding structure 140 may have a curvature at the corner of the first side 140_1. For example, the bonding structure 140 may have an outwards convexly rounded shape at the corner of the first side 140_1.

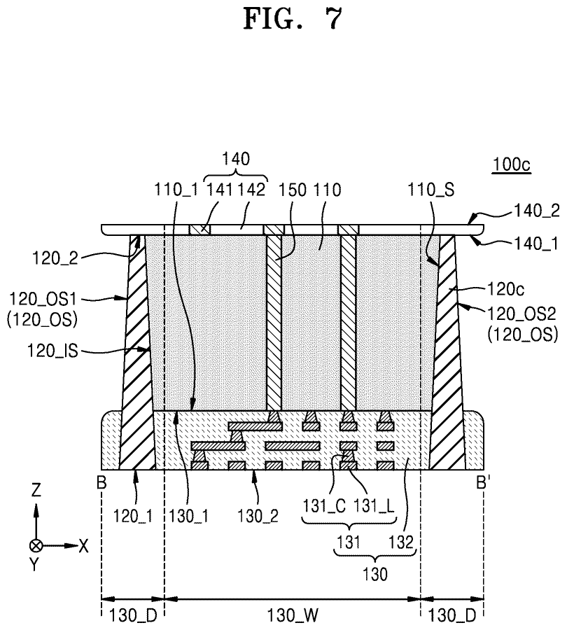

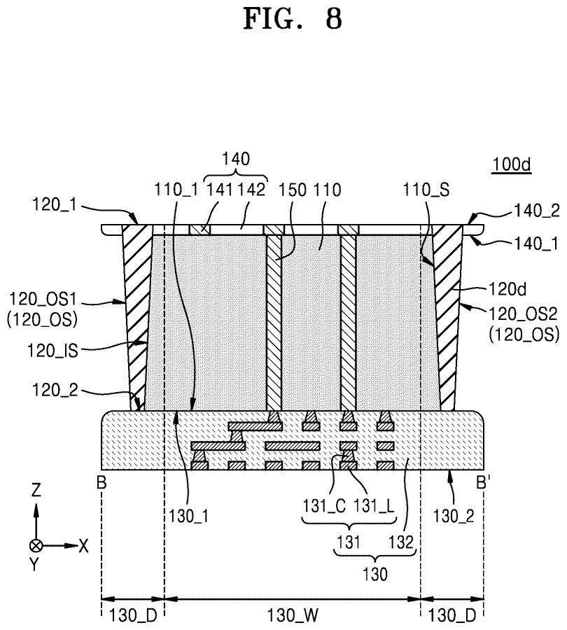

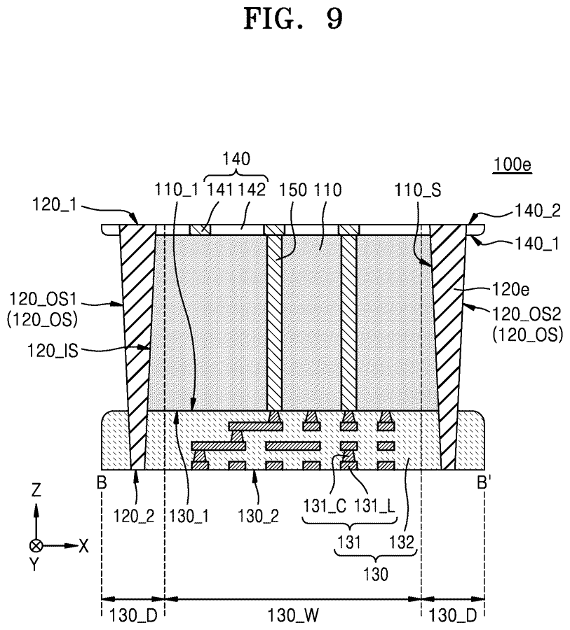

FIG. 7 is a cross-sectional view schematically illustrating a semiconductor chip 100c according to embodiments. FIG. 8 is a cross-sectional view schematically illustrating a semiconductor chip 100d according to embodiments. FIG. 9 is a cross-sectional view schematically illustrating a semiconductor chip 100e according to embodiments. Specifically, FIGS. 7 through 9 are cross-sectional views of the semiconductor chips 100c, 100d, and 100e according to an embodiment, taken along a line B-B′ of FIG. 5.

Most of the components and materials forming the semiconductor chips 100c, 100d, and 100e described below are substantially the same as or similar to those described above with reference to FIG. 6. Thus, for convenience of explanation, the explanation will focus on the differences between the semiconductor chips 100c, 100d, and 100e of FIGS. 7 through 9 and the semiconductor chip 100b of FIG. 6 described above.

The difference between FIGS. 7 through 9 and FIG. 6 is that the length of each of the protective sidewalls 120c, 120d, and 120e of the semiconductor chips 100c, 100d, and 100e of FIGS. 7 through 9 in the vertical direction (Z direction) is different from the length of the protective sidewall 120b of the semiconductor chip 100b of FIG. 6 in the vertical direction (Z direction).

Referring to FIG. 7, the semiconductor chip 100c may include the chip substrate 110, the protective sidewall 120c, the chip wiring structure 130, the bonding structure 140, and the through via 150.

The protective sidewall 120c may penetrate the chip wiring structure 130. The protective sidewall 120c may penetrate the dummy areas 130_D of the chip wiring structure 130. A portion of the outer surface 120_OS of the protective sidewall 120c may be covered by the wiring insulating layer 132 of the chip wiring structure 130. The protective sidewall 120c may have a horizontal width that decreases in a direction away from the second side 130_2 of the chip wiring structure 130.

The first side 120_1 of the protective sidewall 120c may be coplanar with the second side 130_2 of the chip wiring structure 130. The second side 120_2 of the protective sidewall 120c may be coplanar with the second side 110_2 of the chip substrate 110. The length of the protective sidewall 120c in the vertical direction (Z direction) may be equal to the sum of the length of the chip substrate 110 in the vertical direction (Z direction) and the length of the chip wiring structure 130 in the vertical direction (Z direction).

Referring to FIG. 8, the semiconductor chip 100d may include the chip substrate 110, the protective sidewall 120d, the chip wiring structure 130, the bonding structure 140, and the through via 150.

The protective sidewall 120d may penetrate the bonding structure 140. The protective sidewall 120d may penetrate the dummy areas of the bonding structure 140. A portion of the outer side surface 120_OS of the protective sidewall 120d may be covered by the bonding insulating layer 142 of the bonding structure 140. The protective sidewall 120d may have a horizontal width that decreases in a direction away from the chip wiring structure 130.

The first side 120_1 of the protective sidewall 120d may be coplanar with the first side 110_1 of the chip substrate 110. The second side 120_2 of the protective sidewall 120d may be coplanar with the second side 140_2 of the bonding structure 140. The length of the protective sidewall 120d in the vertical direction (Z direction) may be equal to the sum of the length of the chip substrate 110 in the vertical direction (Z direction) and the length of the bonding structure 140 in the vertical direction (Z direction).

Referring to FIG. 9, the semiconductor chip 100e may include the chip substrate 110, the protective sidewall 120e, the chip wiring structure 130, the bonding structure 140, and the through via 150.

The protective sidewall 120e may penetrate the chip wiring structure 130 and the bonding structure 140. The protective sidewall 120e may penetrate the dummy areas 130_D of the chip wiring structure 130 and dummy areas of the bonding structure 140.

A first area of the outer side surface 120_OS of the protective sidewall 120e may be covered by the wiring insulating layer 132 of the chip wiring structure 130. A second area spaced apart from the first area of the outer side surface 120_OS of the protective sidewall 120e in the vertical direction (Z direction) may be covered by the bonding insulating layer 142 of the bonding structure 140. The protective sidewall 120e may have a horizontal width that decreases in a direction away from the second side 130_2 of the chip wiring structure 130.

The first side 120_1 of the protective sidewall 120e may be coplanar with the second side 130_2 of the chip wiring structure 130. The second side 120_2 of the protective sidewall 120e may be coplanar with the second side 140_2 of the bonding structure 140. The length of the protective sidewall 120e in the vertical direction (Z direction) may be equal to the sum of the length of the chip wiring structure 130 in the vertical direction (Z direction) and the length of the bonding structure 140 in the vertical direction (Z direction).

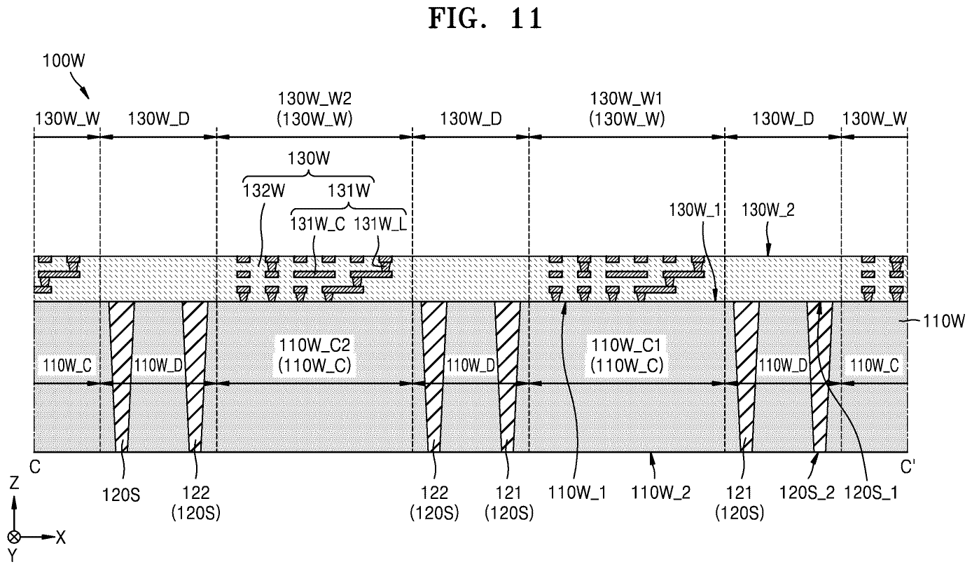

FIG. 10 is a plan view schematically illustrating a semiconductor wafer 100W according to embodiments. FIG. 11 is a cross-sectional view schematically illustrating a portion of the semiconductor wafer 100W according to embodiments.

Specifically, FIG. 10 illustrates a wafer wiring structure 130W transparently, for convenience of explanation of a plurality of protective sidewalls 120S. FIG. 11 is a cross-sectional view of the semiconductor wafer 100W of FIG. 10, taken along a line C-C′ of FIG. 10.

Referring to FIGS. 10 and 11, the semiconductor wafer 100W may include the wafer substrate 110W, the wafer wiring structure 130W, and the plurality of protective sidewalls 120S. The semiconductor wafer 100W may have a shape of a disc before a dicing process is performed on the semiconductor wafer W. For example, the semiconductor wafer 100W may be diced to be separated into the semiconductor chips 100, 100a, 100b, 100c, 100d, and 100e described above.

In some embodiments, the wafer substrate 110W may have a shape before the wafer substrate 110W is separated into the chip substrate (see 110 of FIG. 2), and the wafer wiring structure 130W may have a shape before the wafer wiring structure 130W is separated into the chip wiring structure (see 130 of FIG. 3).

For example, the components and materials of the wafer substrate 110W may be the same as or similar to those of the chip substrate 110 described above. For example, the components and materials of the wafer substrate 130W may be the same as or similar to those of the chip wiring structure 130 described above.

The wafer substrate 110W may include a first side 110W_1 and a second side 110W_2 opposite thereto. The wafer substrate 110W may include a plurality of chip areas 110W_C, and dummy areas 110W_D for defining the plurality of chip areas 110W_C. The plurality of chip areas 110W_C of the wafer substrate 110W may be arranged in a matrix shape. A plurality of individual devices may be positioned on the first side 110W_1 of the wafer substrate 110W. The first side 110W_1 of the wafer substrate 110W may be referred to as a front surface of the wafer substrate 110W, and the second side 110W_2 of the wafer substrate 110W may be referred to as a back surface of the wafer substrate 110W.

The plurality of individual devices may be positioned in the plurality of chip areas 110W_C of the first side 110W_1 of the wafer substrate 110W. For example, the plurality of individual devices may not be positioned in the dummy areas 110W_D of the first side 110W_1 of the wafer substrate 110W. For example, a portion of the dummy areas 110W_D of the wafer substrate 110W may be removed so that the wafer substrate 110W may be separated into the chip substrate 110 of the semiconductor chip 100.

The wafer wiring structure 130W may be disposed on the first side 110W_1 of the wafer substrate 110W. The wafer wiring structure 130W may include a first side 130W_1 that contacts the first side 110W_1 of the wafer substrate 110W, and a second side 130W_2 opposing the first side 130W_1. The wafer wiring structure 130W may cover the first side 110W_1 of the wafer substrate 110W. For example, the side surface of the wafer wiring structure 130W may be coplanar with the side surface of the wafer substrate 110W.

The wafer wiring structure 130W may include a plurality of wiring areas 130W_W, and dummy areas 130W_D for defining the plurality of wiring areas 130W_W. The plurality of wiring areas 130W_W of the wafer wiring structure 130W may overlap the plurality of chip areas 110W_C of the wafer substrate 110W in the vertical direction (Z direction), and the plurality of wiring areas 130W_W of the wafer wiring structure 130W may correspond to the plurality of chip areas 110W_C of the wafer substrate 110W, respectively.

A portion of the dummy areas 130W_D of the wafer wiring structure 130W may be removed so that the wiring area 130W_W of the wafer wiring structure 130W may be separated into the wiring area 130_W of the chip wiring structure 130 of the semiconductor chip 100.

The wafer wiring structure 130W may include a plurality of wiring patterns 131W and a wafer wiring insulating layer 132W that surrounds the plurality of wiring patterns 131W. The plurality of wiring patterns 131W may each include wiring lines 131W_L that extend in the horizontal direction, and wiring contacts 131W_C that extend from the wiring lines 131W_L in the vertical direction (Z direction).

The plurality of wiring patterns 131W may be positioned in the plurality of wiring areas 130W_W of the wafer wiring structure 130W, respectively. The wafer wiring insulating layer 132W may be positioned in the dummy areas 130W_D of the wafer wiring structure 130W. For example, wiring patterns positioned in different wiring areas of the plurality of wiring patterns 131W may not be electrically connected to each other.

For example, the plurality of chip areas 110W_C of the wafer substrate 110W may include a first chip area 110W_C1 and a second chip area 110W_C2. The plurality of wiring areas 130W_W of the wafer wiring structure 130W may include a first wiring area 130W_W1 and a second wiring area 130W_W2. The first chip area 110W_C1 of the wafer substrate 110W may overlap the first wiring area 130W_W1 of the wafer wiring structure 130W in the vertical direction (Z direction) and may be electrically connected to each other. The second chip area 110W_C2 of the wafer substrate 110W may overlap the second wiring area 130W_W2 of the wafer wiring structure 130W and may be electrically connected to each other. Wiring patterns positioned within the first wiring area 130W_W1 and wiring patterns within the second wiring area 130W_W2 may be electrically separated from each other.

The plurality of protective sidewalls 120S may penetrate the wafer substrate 110W. For example, the plurality of protective sidewalls 120S may be positioned within the dummy areas 110W_D of the wafer substrate 110W. For example, the plurality of protective sidewalls 120S may overlap the dummy areas 130W_D of the wafer wiring structure 130W in the vertical direction (Z direction).

The plurality of protective sidewalls 120S may be spaced apart from each other in the horizontal direction. The plurality of protective sidewalls 120S may be arranged in a matrix shape. The dummy areas 110W_D1 of the wafer substrate 110W may be positioned in a separation space between the plurality of protective sidewalls 120S. A portion of the dummy areas 130W_D of the wafer wiring structure 130W may be positioned on the upper portion of a portion positioned between the plurality of protective sidewalls 120S among the dummy areas 110W_D of the wafer substrate 110W. For example, the portion positioned between the plurality of protective sidewalls 120S among the dummy areas 110W_D of the wafer substrate 110W may be removed in a subsequent dicing process.

The plurality of chip areas 110W_C of the wafer substrate 110W may be respectively positioned in a space surrounded by each of the plurality of protective sidewalls 120S. In a plan view, the plurality of chip areas 110W_C of the wafer substrate 110W may have a square shape, and each of the plurality of protective sidewalls 120S may have a square ring shape in which the plurality of chip areas 110W_C are respectively positioned.

In some embodiments, the plurality of protective sidewalls 120S may include a first protective sidewall 121 and a second protective sidewall 122. The first chip area 110W_C1 of the wafer substrate 110W may be positioned in the internal space of the first protective sidewall 121, and the second chip area 110W_C2 of the wafer substrate 110W may be positioned in the internal space of the second protective sidewall 122. The dummy areas 110W_D of the wafer substrate 110W may be positioned between the first protective sidewall 121 and the second protective sidewall 122. A portion of the dummy areas 130W_D of the wafer wiring structure 130W may be positioned in the dummy areas 110W_D of the wafer substrate 110W positioned between the first protective sidewall 121 and the second protective sidewall 122.

The plurality of protective sidewalls 120S may each include a first side 120S_1 and a second side 120S_2 opposite thereto. The first side 120S_1 of each of the plurality of protective sidewalls 120S may be coplanar with the first side 110W_1 of the wafer substrate 110W and may be in contact with the first side 130W_1 of the wafer wiring structure 130W. The second side 120S_2 of each of the plurality of sidewalls 120S may be coplanar with the second side 110W_2 of the wafer substrate 110W. The length of each of the plurality of protective sidewalls 120S in the vertical direction (Z direction) may be equal to the length of the wafer substrate 110W in the vertical direction (Z direction).

The plurality of protective sidewalls 120S may have a horizontal width that decreases in a direction away from the wafer wiring structure 130W. For example, the plurality of protective sidewalls 120S may have a horizontal width that decreases in a direction away from the wafer wiring structure 130W. In addition, the plurality of protective sidewalls may have a horizontal width that increases in a direction away from the wafer wiring structure 130W.

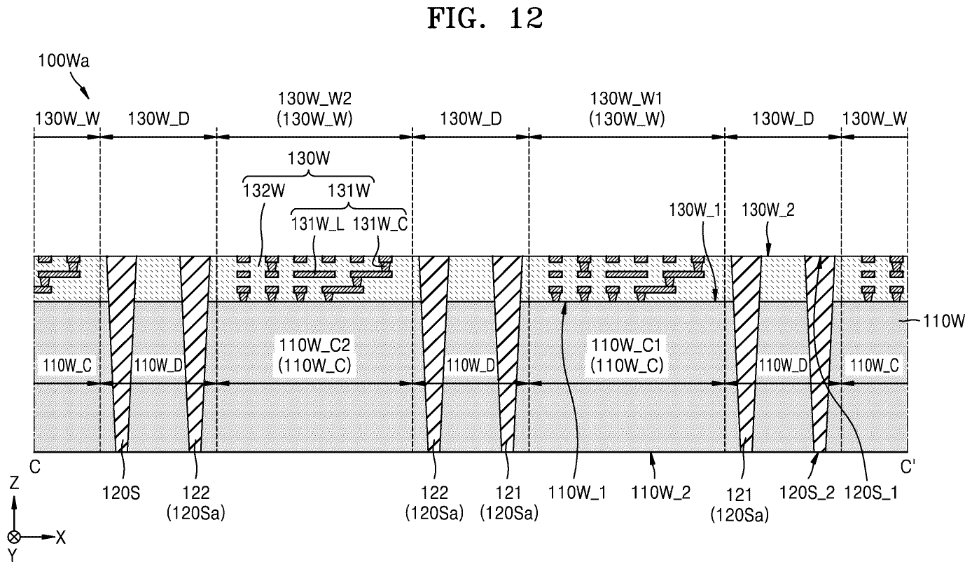

FIG. 12 is a cross-sectional view schematically illustrating a portion of the semiconductor wafer 100Wa according to embodiments. Specifically, FIG. 12 is a cross-sectional view of the semiconductor wafer 100Wa, taken along the line C-C′ of FIG. 10.

Most of the components and materials forming the semiconductor wafer 100Wa described below are substantially the same as or similar to those described above with reference to FIG. 11. Therefore, for convenience of explanation, the difference between the semiconductor wafer 100Wa of FIG. 12 and the semiconductor wafer 100Wa of FIG. 11 described above will be explained.

The difference between FIG. 12 and FIG. 11 is that the length of each of the plurality of protective sidewalls 120Sa of the semiconductor wafer 100Wa of FIG. 12 in the vertical direction (Z direction) is different from the length of each of the plurality of protective sidewalls 120S of the semiconductor wafer 100W of FIG. 11 in the vertical direction (Z direction).

Referring to FIG. 12, the semiconductor wafer 100Wa may include the wafer substrate 110W, the wafer wiring structure 130W, and a plurality of protective sidewalls 120Sa.

The plurality of protective sidewalls 120Sa may penetrate the wafer wiring structure 130W. A second side 120S_2 of each of the plurality of protective sidewalls 120Sa may be coplanar with the second side 110W_2 of the wafer substrate 110W. Each of the plurality of protective sidewalls 120Sa may penetrate the wafer wiring structure 130W so that the first side 120S_1 of each of the plurality of protective sidewalls 120Sa may be coplanar with the second side 130W_2 of the wafer wiring structure 130W. For example, the length of each of the plurality of protective sidewalls 120Sa in the vertical direction (Z direction) may be equal to the sum of the length of the wafer substrate 110W in the vertical direction (Z direction) and the length of the wafer wiring structure 130W in the vertical direction (Z direction).

The plurality of protective sidewalls 120Sa may penetrate the dummy areas 130W_D of the wafer wiring structure 130W. For example, the plurality of protective sidewalls 120Sa may be spaced apart from the plurality of wiring areas 130W_W of the wafer wiring structure 130W. For example, the plurality of protective sidewalls 120Sa may be spaced apart from the plurality of wiring patterns 131W of the wafer wiring structure 130W so as to secure a margin distance.

The plurality of protective sidewalls 120Sa may each have a horizontal width that decreases in a direction away from the second side 130W_2 of the wafer wiring structure 130W. A portion of the outer side surface of each of the plurality of protective sidewalls 120Sa may be covered by the wafer wiring insulating layer 132W of the wafer wiring structure 130W.

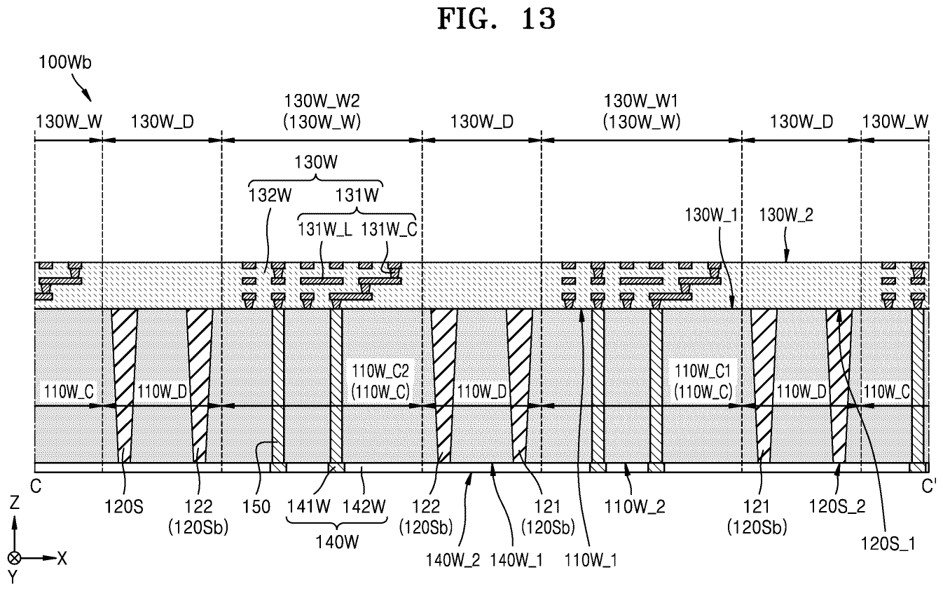

FIG. 13 is a cross-sectional view schematically illustrating a portion of a semiconductor wafer 100Wb according to embodiments. Specifically, FIG. 13 is a cross-sectional view schematically illustrating the semiconductor wafer 100Wb, taken along the line C-C′ of FIG. 10.

Most of the components and materials forming the semiconductor wafer 100Wb described below are substantially the same as or similar to those described above with reference to FIG. 11. Thus, for convenience of explanation, the difference between the semiconductor wafers 100Wb, 100Wc, 100Wd, and 100We of FIGS. 13 to 16 and the semiconductor wafer 100W of FIG. 11 described above will be mainly explained.

Referring to FIG. 13, the semiconductor wafer 100Wb may include the wafer substrate 110W, the wafer wiring structure 130W, a plurality of protective sidewalls 120Sb, the wafer bonding structure 140W, and the through via 150. The semiconductor wafer 100Wb of FIG. 13 is different from the semiconductor wafer 100Wb of FIG. 11 in that the semiconductor wafer 100Wb of FIG. 13 includes the wafer bonding structure 140W and the through via 150.

The through via 150 may penetrate the wafer substrate 110W. The through via 150 may be positioned inside the plurality of chip areas 110W_C of the wafer substrate 110W. The through via 150 may extend from the first side 110W_1 of the wafer substrate 110W to the second side 110W_2 of the wafer substrate 110W in the vertical direction (Z direction).

The through via 150 may be electrically connected to the wafer wiring structure 130W. The through via 150 may be electrically connected to the plurality of wiring patterns 131W of the wafer wiring structure 130W. The through via 150 may overlap one of the plurality of wiring areas 130W_W of the wafer wiring structure 130W in the vertical direction (Z direction). In some embodiments, the through via 150 may include copper, nickel, stainless steel or beryllium copper.

The wafer bonding structure 140W may be positioned on the second side 110W_2 of the wafer substrate 110W. The wafer bonding structure 140W may include a first side 140W_1 that contacts the second side 110W_2 of the wafer substrate 110W, and a second side 140W_2 opposing the first side 140W_1. In some embodiments, the wafer bonding structure 140W may completely cover the second side 110W_2 of the wafer substrate 110W. The side surface of the wafer bonding structure 140W may be coplanar with the side surface of the wafer substrate 110W.

The wafer bonding structure 140W may include a plurality of pattern areas and dummy areas for defining the plurality of pattern areas. Each of the plurality of pattern areas of the wafer bonding structure 140W may overlap each of the plurality of chip areas 110W_C of the wafer substrate 110W in the vertical direction (Z direction). The dummy areas of the wafer bonding structure 140W may overlap the dummy areas 110W_D of the wafer substrate 110W in the vertical direction. For example, a portion of the dummy areas of the wafer bonding structure 140W may be removed so that the wafer bonding structure 140W may be separated into the bonding structures (see 140 of FIG. 6) of the semiconductor chip (see 100c of FIG. 6).

The wafer bonding structure 140W may include a plurality of bonding patterns 141W and a wafer bonding insulating layer 142W that surrounds the plurality of bonding patterns 141W. The plurality of bonding patterns 141W may be arranged in the plurality of pattern areas, respectively, and the plurality of bonding patterns 141W may be spaced apart from the plurality of pattern areas with the dummy areas of the wafer bonding structure 140W therebetween. Two bonding patterns positioned in different pattern areas among the plurality of bonding patterns 141W may not be electrically connected to each other.

The bonding patterns 141W of the wafer bonding structure 140W may be respectively connected to the through via 150. The through via 150 may be configured to electrically connect the plurality of bonding patterns 141W of the wafer bonding structure 140W to each of the plurality of wiring patterns 131W of the wafer wiring structure 130W. For example, bonding patterns and wiring patterns positioned at upper and lower portions of the first chip area 110W_C1 of the wafer substrate 110W may be electrically connected to each other through the through via 150.

The plurality of protective sidewalls 120Sb may overlap the dummy areas of the wafer bonding structure 140W in the vertical direction (Z direction). The plurality of protective sidewalls 120Sb may be spaced apart from the plurality of pattern areas of the wafer bonding structure 140W. For example, the wafer bonding structure 140W may be positioned on the portion positioned between the plurality of protective sidewalls 120Sb among the dummy areas 110W_D of the wafer substrate 110W.

The first side 120Sb_1 of each of the plurality of protective sidewalls 120Sb may be coplanar with the first side 110W_1 of the wafer substrate 110W and may be in contact with the wafer wiring structure 130W. The second side 120Sb_2 of each of the plurality of protective sidewalls 120Sb may be coplanar with the second side 110W_2 of the wafer substrate 110W and may be in contact with the wafer bonding structure 140W. The length of each of the plurality of protective sidewalls 120Sb in the vertical direction (Z direction) may be equal to the length of the wafer substrate 110W in the vertical direction (Z direction).

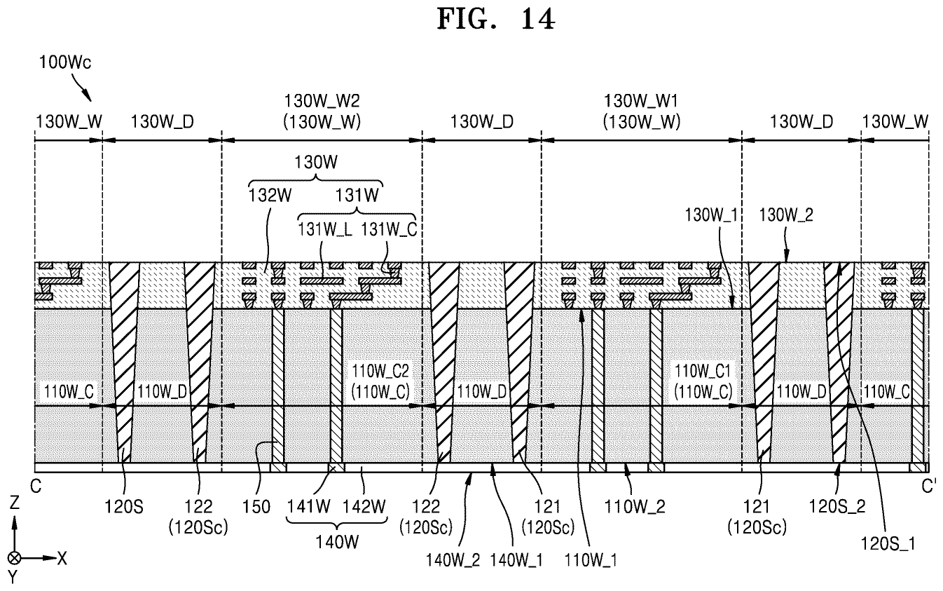

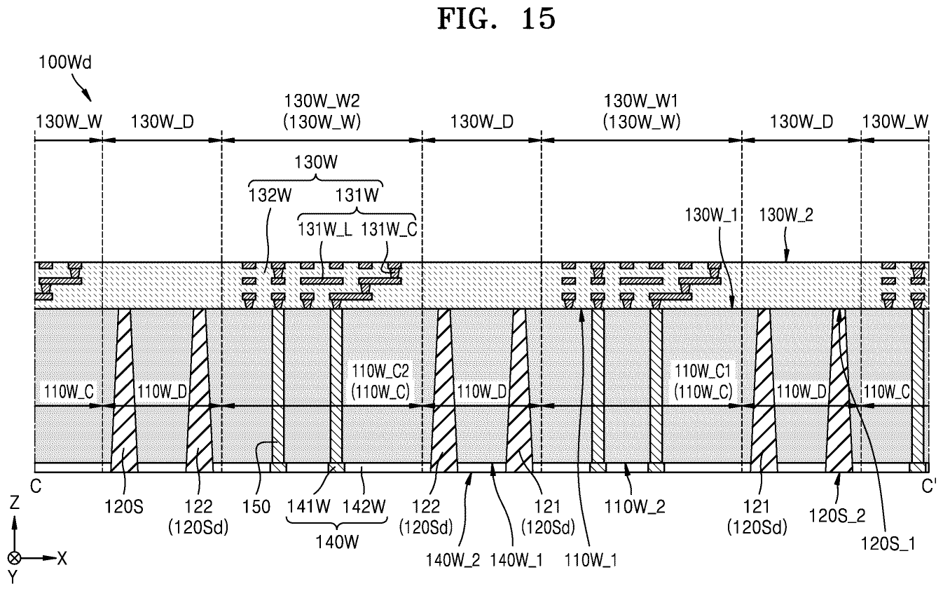

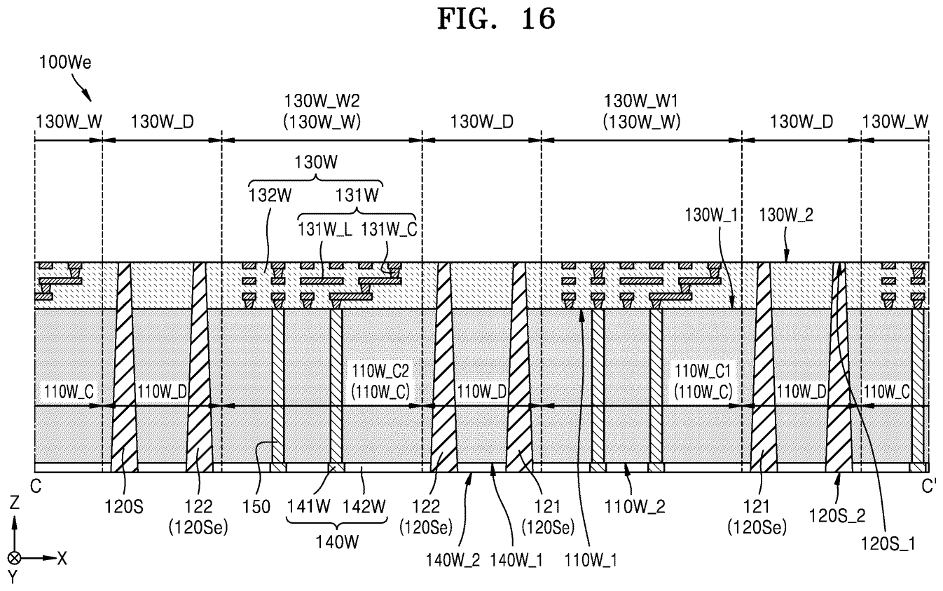

FIG. 14 is a cross-sectional view schematically illustrating a portion of a semiconductor wafer 100Wc according to embodiments. FIG. 15 is a cross-sectional view schematically illustrating a portion of a semiconductor wafer 100Wd according to embodiments. FIG. 16 is a cross-sectional view schematically illustrating a portion of a semiconductor wafer 100We according to embodiments. Specifically, FIGS. 14 through 16 are cross-sectional views schematically illustrating the semiconductor wafers 100Wc, 100Wd, and 100We, taken along the line C-C′ of FIG. 10.

Most of the components and materials forming the semiconductor wafers 100Wc, 100Wd, and 100We described below are substantially the same as or similar to those described above with reference to FIG. 13. Therefore, for convenience of explanation, the explanation will focus on the differences between the semiconductor wafers 100Wc, 100Wd, and 100We of FIGS. 14 to 16 and the semiconductor wafer 100Wb of FIG. 13 described above.

The difference between FIGS. 14 through 16 and FIG. 13 is that the length of each of the plurality of protective sidewalls 120Sc, 120Sd, and 120Se) of the semiconductor wafers 100Wc, 100Wd, and 100We of FIGS. 14 through 16 in the vertical direction (Z direction) is different from the length of the plurality of protective sidewalls 120Sb of the semiconductor wafer 100Wb of FIG. 13 in the vertical direction (Z direction).

Referring to FIG. 14, the semiconductor wafer 100Wc may include the wafer substrate 110W, the wafer wiring structure 130W, a plurality of protective sidewalls 120Sc, the through via 150, and the wafer bonding structure 140W.

The plurality of protective sidewalls 120Sc may penetrate the wafer wiring structure 130W. The plurality of protective sidewalls 120Sc may penetrate the dummy areas 130W_D of the wafer wiring structure 130W. A portion of the outer side surface of each of the plurality of protective sidewalls 120Sc may be covered by the wafer wiring insulating layer 132W of the wafer wiring structure 130W. The plurality of protective sidewalls 120Sc may have a horizontal width that decreases in a direction away from the second side 130W_2 of the wafer wiring structure 130W.

The first side 120S_1 of each of the plurality of protective sidewalls 120Sc may be coplanar with the second side 130_2 of the wafer wiring structure 130W. The second side 120S_2 of each of the plurality of protective sidewalls 120Sc may be coplanar with the second side 110W_2 of the wafer substrate 110W. The length of the plurality of protective sidewalls 120Sc in the vertical direction (Z direction) may be equal to the sum of the length of the wafer substrate 110W in the vertical direction (Z direction) and the length of the wafer wiring structure 130W in the vertical direction (Z direction).

Referring to FIG. 15, the semiconductor wafer 100Wd may include the wafer substrate 110W, a plurality of protective sidewalls 120Sd, the wafer wiring structure 130W, the wafer bonding structure 140W, and the through via 150.

The plurality of protective sidewalls 120Sd may penetrate the wafer bonding structure 140W. The plurality of protective sidewalls 120Sd may penetrate the dummy area of the wafer bonding structure 140W. A portion of the outer side surface of each of the plurality of protective sidewalls 120Sd may be covered by the wafer bonding insulating layer 142W of the wafer bonding structure 140W. The plurality of protective sidewalls may each have a horizontal width that increases in a direction away from the wafer wiring structure 130W.

The first side 120S_1 of each of the plurality of protective sidewalls 120Sd may be coplanar with the first side 110W_1 of the wafer substrate 110W. The second side 120S_2 of each of the plurality of protective sidewalls 120Sd may be coplanar with the second side 140W_2 of the wafer bonding structure 140W. The length of the plurality of protective sidewalls 120Sd in the vertical direction (Z direction) may be equal to the sum of the length of the wafer substrate 110W in the vertical direction (Z direction) and the length of the wafer bonding structure 140W in the vertical direction (Z direction).

Referring to FIG. 16, the semiconductor wafer 100We may include the wafer substrate 110W, the plurality of protective sidewalls 120We, the wafer wiring structure 130W, the wafer bonding structure 140W, and the through via 150.

The plurality of protective sidewalls 120Se may penetrate the wafer wiring structure 130W and the wafer bonding structure 140W. The plurality of protective sidewalls 120Se may each penetrate the dummy areas 130W_D of the wafer wiring structure 130W and the dummy area of the wafer bonding structure 140W.

A first area of the outer side surface of each of the plurality of protective sidewalls 120Se may be covered by the wafer wiring insulating layer 132W of the wafer wiring structure 130W. A second area spaced apart from the first area of the outer side surface of the plurality of protective sidewalls 120Se in the vertical direction (Z direction) may be covered by the wafer bonding insulating layer 142W of the wafer bonding structure 140W. Each of the plurality of protective sidewalls 120Se may have a horizontal width in a direction away from the second side 130W_2 of the wafer wiring structure 130W.

The first side 120S_1 of each of the plurality of protective sidewalls 120Se may be coplanar with the second side 130W_2 of the wafer wiring structure 130W. The second side 120_2 of each of the protective sidewalls 120Se may be coplanar with the second side 140W_2 of the wafer bonding structure 140W. The length of each of the protective sidewalls 120Se in the vertical direction (Z direction) may be equal to the sum of the length of the chip substrate 110 in the vertical direction (Z direction), the length of the wafer wiring structure 130W in the vertical direction (Z direction), and the length of the wafer bonding structure 140W in the vertical direction (Z direction).

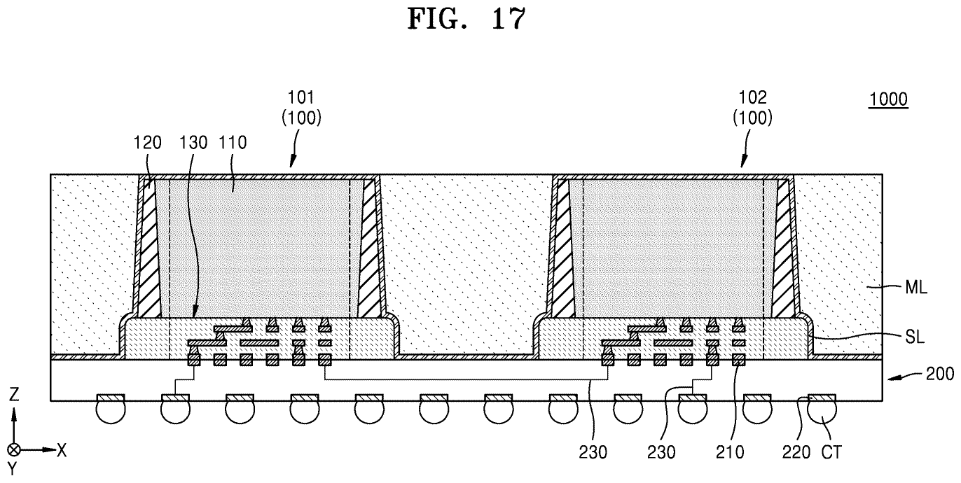

FIG. 17 is a cross-sectional view schematically illustrating a semiconductor package 1000 according to embodiments.

Referring to FIG. 17 with FIG. 3, the semiconductor package 1000 may include a package substrate 200, a semiconductor chip 100, and a molding layer ML.

The package substrate 200 may be a printed circuit board (PCB). However, embodiments are not limited thereto, and the package substrate 200 may be an interposer. A plurality of semiconductor chips may be mounted on the package substrate 200. The semiconductor chip 100 may be one among the semiconductor chips 100, 100a, 100b, 100c, 100d, and 100e described above.

The package substrate 200 may include a core insulating layer including at least one material selected from the group consisting of a phenol resin, an epoxy resin, and polyimide. For example, the core insulating layer may include at least one material selected from the group consisting of polyimide, flame retardant 4 (FR-4), tetrafunctional epoxy, polyphenylene ether, epoxy/polyphenylene oxide, bismaleimide triazine (BT), Thermount, cyanate ester, and liquid crystal polymer.

In some embodiments, the package substrate 200 may include an upper pad 210 positioned on an upper surface of the core insulating layer, and a lower pad 220 positioned on a lower surface of the core insulating layer. The upper pad 210 and the lower pad 220 may be a portion of a circuit wiring that is patterned after the upper surface and the lower surface of the core insulating layer are coated with a copper (Cu) foil. Specifically, the upper pad 210 and the lower pad 220 may be an area of the circuit wiring that is not covered by a solder resist layer and exposed to the outside. In some embodiments, the upper pad 210 and the lower pad 220 may each include copper, nickel, stainless steel or beryllium copper.

An internal wiring 230 for electrically connecting the upper pad 210 to the lower pad 220 may be formed in the package substrate 200. In some embodiments, the internal wiring 230 may be configured to electrically connect one upper pad 210 to another upper pad 210.

In some embodiments, external connection terminals CT may be attached to the lower pad 220. The external connection terminals CT may be configured to electrically and physically connect between the package substrate 200 and an external devices on which the package substrate 200 is mounted. The external connection terminals CT may be formed from solder balls or solder bumps, for example.

The semiconductor chip 100 may be mounted on the package substrate 200. The chip wiring structure 130 of the semiconductor chip 100 may face the package substrate 200. The chip wiring structure 130 of the semiconductor chip 100 may be electrically connected to the upper pad 210 of the package substrate 200. The semiconductor chip 100 may be electrically connected to the package substrate 200 using a copper-copper bonding method. However, embodiments are not limited thereto, and the semiconductor chip 100 may be electrically connected to the package substrate 200 through a chip connection terminal or a conductive adhesive film.

In some embodiments, a first semiconductor chip 101 and a second semiconductor chip 102 may be mounted on the package substrate 200. For example, the first semiconductor chip 101 and the second semiconductor chip 102 may be semiconductor chips having different functions. The number of semiconductor chips 100 mounted on the package substrate 200 is not limited thereto. The package substrate 200 may electrically connect the first semiconductor chip 101 to the second semiconductor chip 102.

The molding layer ML may be positioned on the wafer substrate 200 and may surround the semiconductor chip 100. The molding layer ML may cover a side surface 130_S of the chip wiring structure 130 of the semiconductor chip 100 and an outer side surface 120_OS of the protective sidewalls 120. In some embodiments, the molding layer ML may cover a portion of the first side 130_1 of the chip wiring structure 130 of the semiconductor chip 100.

In some embodiments, an upper surface of the molding layer ML may be coplanar with the upper surface of the semiconductor chip 100, for example, the second side 110_2 of the chip substrate 110 of the semiconductor chip 100. The side surface of the molding layer ML may be coplanar with the side surface of the package substrate 200. The molding layer ML may protect the semiconductor chip 100 and the package substrate 200 from external shock.

In some embodiments, the semiconductor package 1000 may further include a subsidiary layer SL. The subsidiary layer SL may be disposed between the package substrate 200 and the molding layer ML and between the semiconductor chip 100 and the molding layer ML. The subsidiary layer SL may be conformally formed. For example, the subsidiary layer SL may be silicon nitride. The subsidiary layer SL may be configured to reinforce a bonding force between the molding layer ML and the package substrate 200 and a bonding force between the molding layer ML and the semiconductor chip 100.

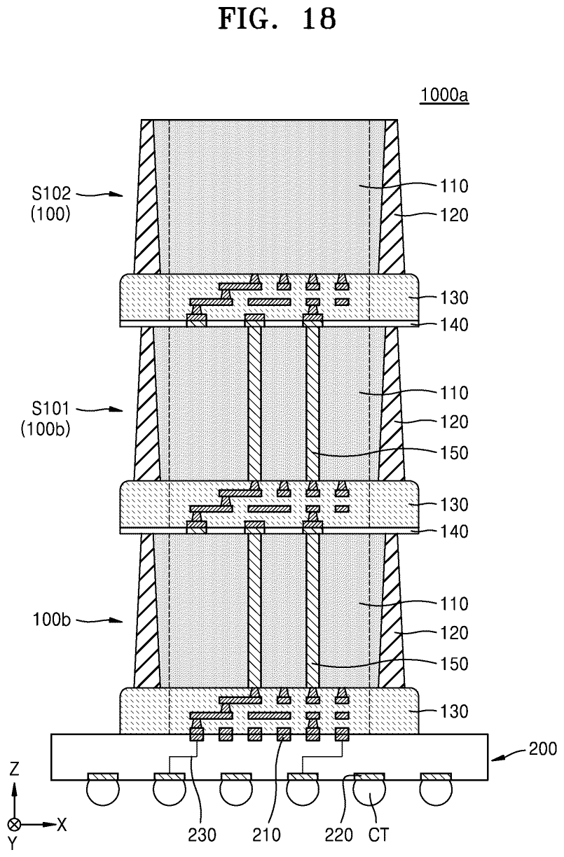

FIG. 18 is a cross-sectional view schematically illustrating a semiconductor package 1000a according to embodiments.

Referring to FIG. 18 with FIGS. 3 and 6, the semiconductor package 1000 may include the package substrate 200, the semiconductor chip 100b, a first stack semiconductor chip S101, and a second stack semiconductor chip S102. The semiconductor chip 100b, the first stack semiconductor chip S101, and the second stack semiconductor chip S102 may be referred to as a stack structure or stacked semiconductor chips.

In FIG. 18, three semiconductor chips are stacked, but the number of stacked semiconductor chips is not limited thereto. The semiconductor chip 100b, the first stack semiconductor chip S101, and the second stack semiconductor chip S102 may be one among the semiconductor chips 100, 100a, 100b, 100c, 100d, and 100e described above.

For example, the semiconductor chip 100b and the first stack semiconductor chip S101 of FIG. 18 may be the semiconductor chip 100b of FIG. 6, and the second semiconductor chip S102 may be the semiconductor chip 100 of FIG. 3. For example, the semiconductor chip 100b and the first stack semiconductor chip S101 may include the bonding structure 140, and the bonding structure 140 may be omitted from the second stack semiconductor chip S102 positioned at the top.

The semiconductor chip 100b may be mounted on the package substrate 200. The semiconductor chip 100b may be mounted on the package substrate 200 so that the chip wiring structure 130 may face the package substrate 200. For example, the semiconductor chip 100b may be positioned at the lowest layer of the stack structure and may be in contact with the package substrate 200.

The first stack semiconductor chip S101 may be stacked on the semiconductor chip 100b. For example, the first stack semiconductor chip S101 may be bonded to the bonding structure 140 of the semiconductor chip 100b. For example, the chip wiring structure 130 of the first stacked semiconductor chip S101 may be electrically connected to the bonding structure 140 of the semiconductor chip 100b through hybrid bonding.

For example, the wiring insulating layer 132 of the chip wiring structure 130 of the first stacked semiconductor chip S101 may be bonded to the bonding insulating layer 142 of the bonding structure 140 of the semiconductor chip 100b, and the wiring pattern 131 of the chip wiring structure 130 of the first stacked semiconductor chip S101 may be bonded to the bonding pattern 141 of the bonding structure 140 of the semiconductor chip 100b.

However, embodiments are not limited thereto, and the semiconductor chip 100b and the first stack semiconductor chip S101 may be bonded to each other by a chip connection terminal such as solder ball or a solder bump or may be bonded to each other using a conductive adhesive film.

The second stack semiconductor chip S102 may be stacked on the first stack semiconductor chip S101. For example, the second stack semiconductor chip S102 may be bonded to the bonding structure 140 of the first stack semiconductor chip S101. For example, the chip wiring structure 130 of the second stack semiconductor chip S102 may be electrically connected to the bonding structure 140 of the first stack semiconductor chip S101 through hybrid bonding. However, embodiments are not limited thereto, and the first stack semiconductor chip S101 and the second stack semiconductor chip S102 may be bonded to each other by a chip connection terminal such as a solder ball or solder bump, or may be bonded to each other through a conductive adhesive film.

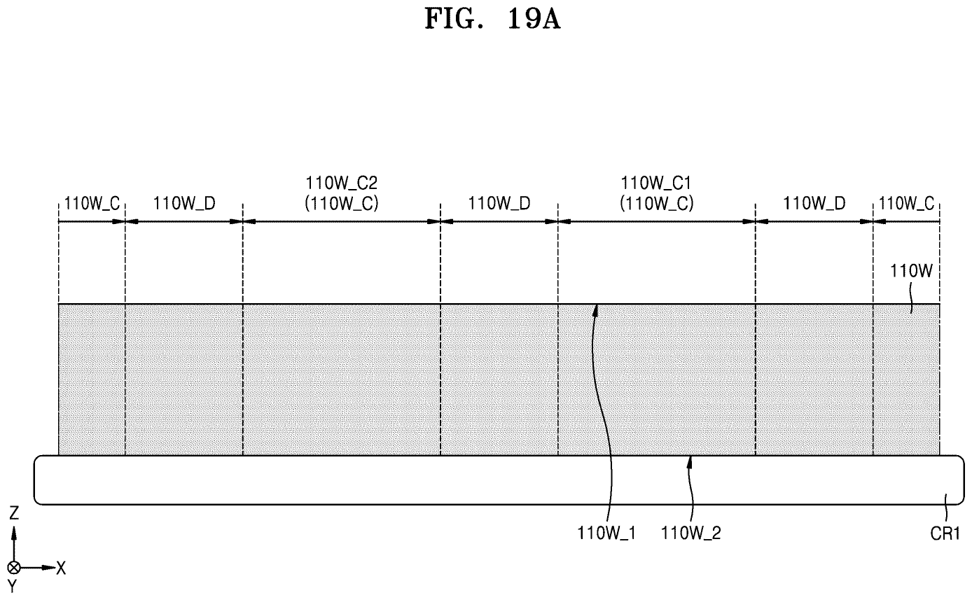

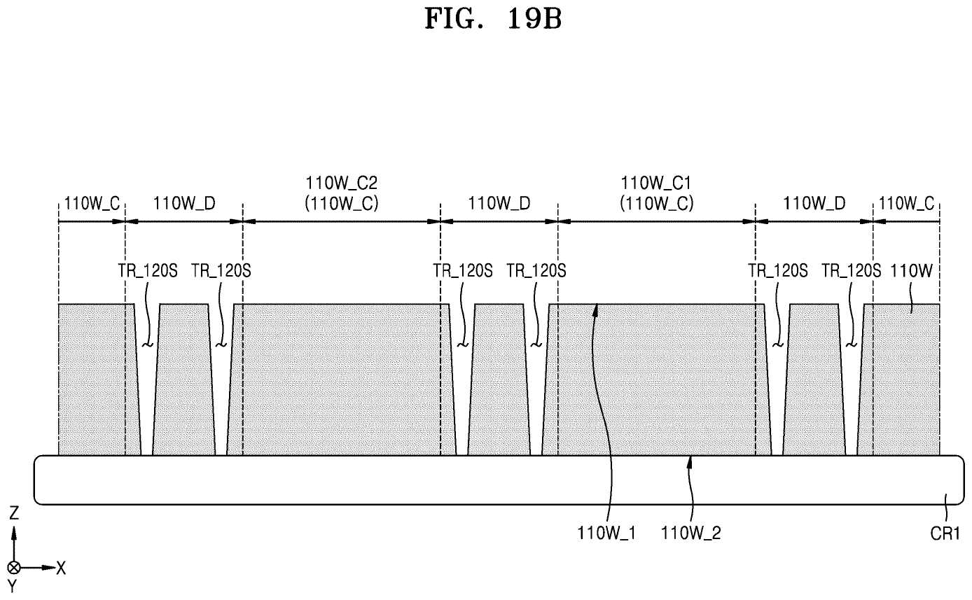

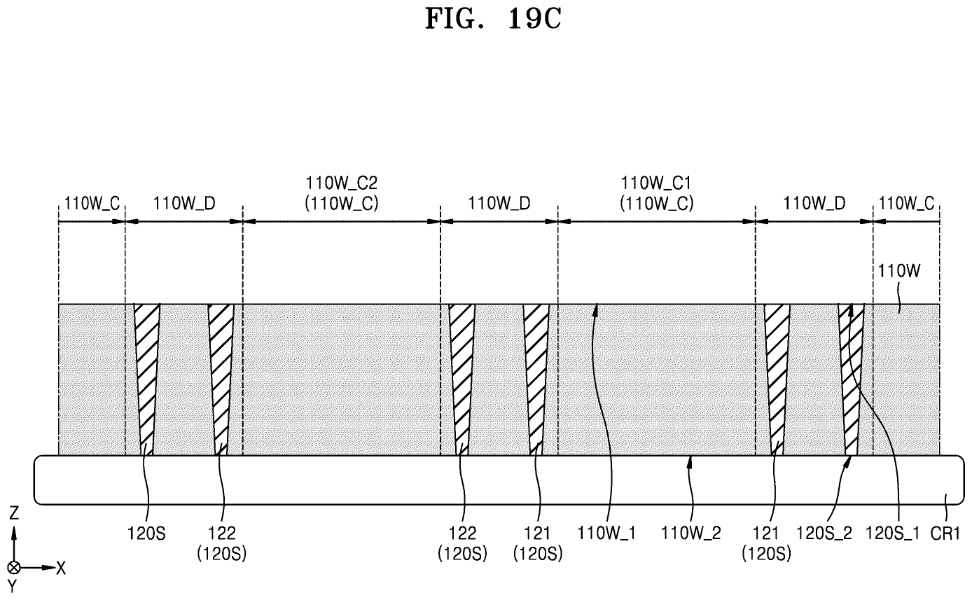

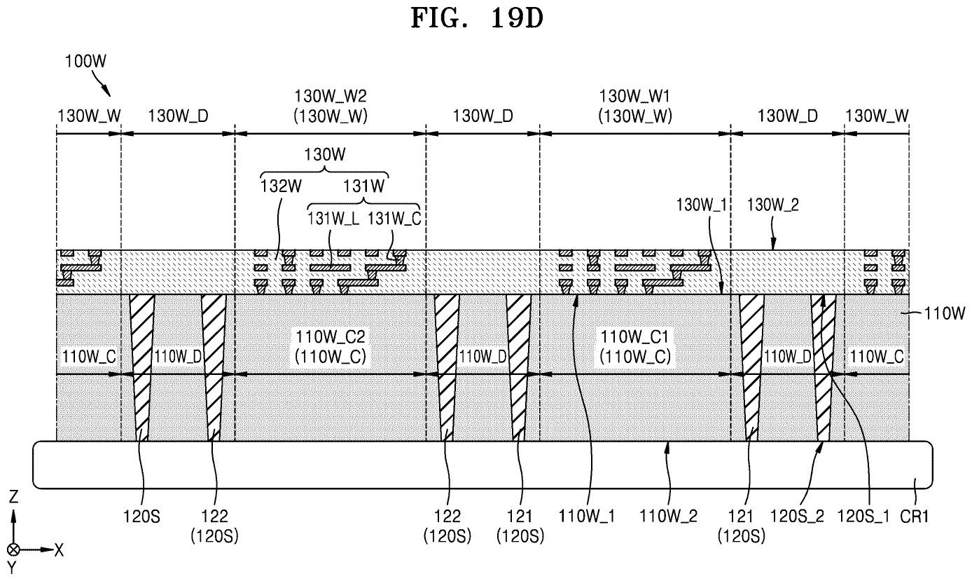

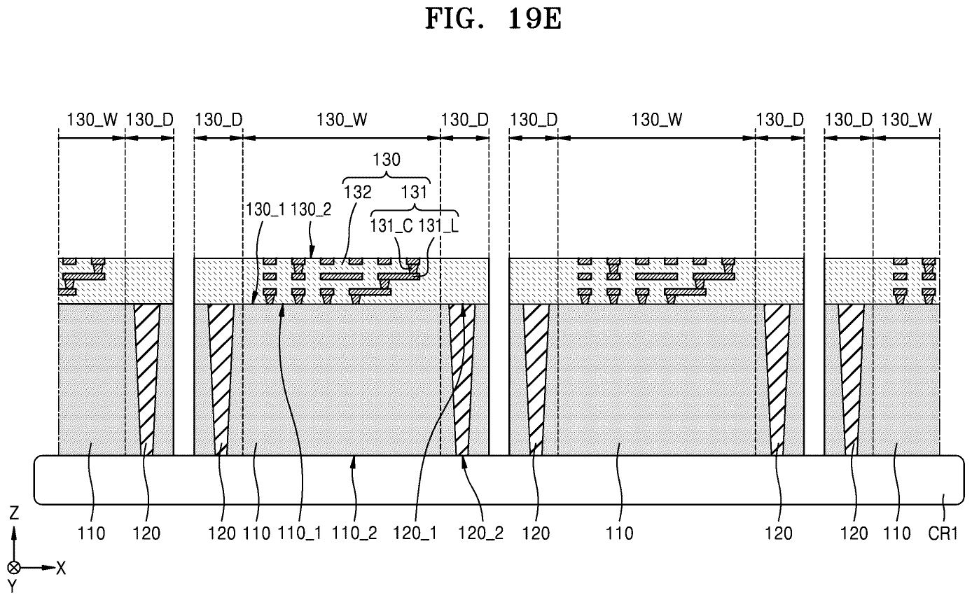

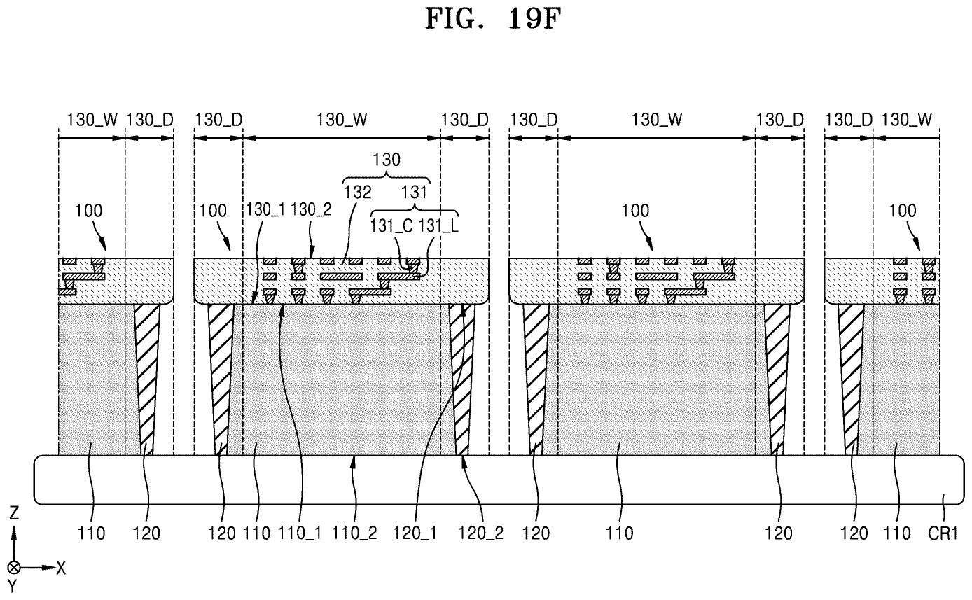

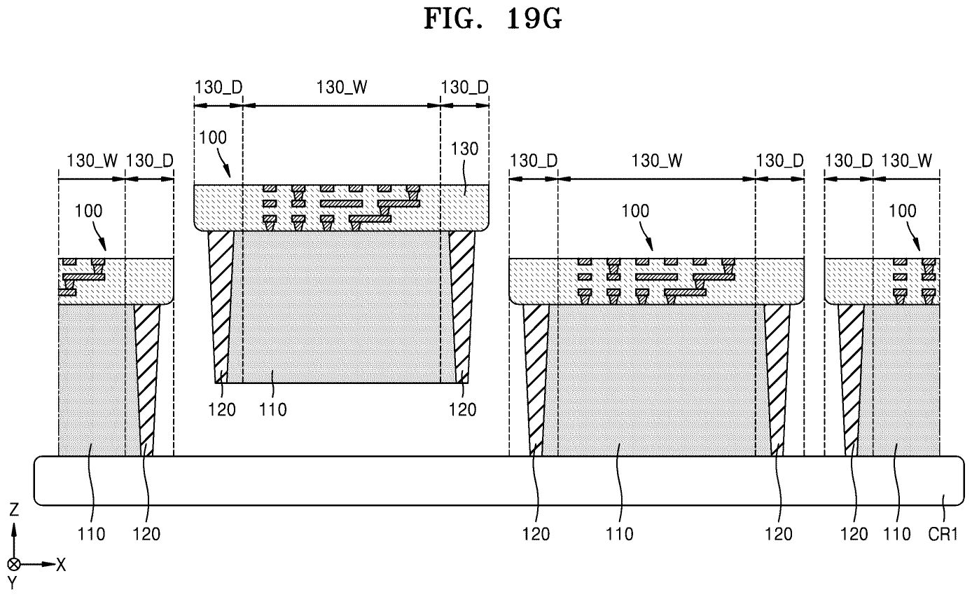

FIGS. 19A through 19G are cross-sectional views illustrating a method of manufacturing a semiconductor chip according to embodiments in a process sequence. Specifically, FIGS. 19A through 19D illustrate an operation of manufacturing the semiconductor wafer 100W shown in FIG. 11 in a process sequence. FIGS. 19E through 19G illustrate an operation of cutting the semiconductor wafer 100W to separate the semiconductor wafer 100W into the semiconductor chips 100 shown in FIG. 3 in a process sequence.

Referring to FIG. 19A, the wafer substrate 110W may be mounted on a first carrier substrate CR1. In some embodiments, the wafer substrate 110W may be mounted on the first carrier substrate CR1 through an adhesive film.

The wafer substrate 110W may have a disc shape and may include a first side 110W_1 and a second side 110W_2 opposite thereto. The first side 110W_1 of the wafer substrate 110W may be a side on which a plurality of individual devices are positioned, and the second side 110W_2 of the wafer substrate 110W may face the first carrier substrate CR1.

For example, the wafer substrate 110W may be classified into a plurality of chip areas 110W_C and dummy areas 110W_D for defining the plurality of chip areas 110W_C. The plurality of chip areas 110W_C may be arranged in a matrix shape. Each of the plurality of chip areas 110W_C of the wafer substrate 110W may be an area to be separated into the semiconductor chips 100 later.

The first chip area 110W_C1 and the second chip area 110W_2 of the wafer substrate 110W may be spaced apart from each other with the dummy areas 110W_D therebetween. Through a subsequent dicing process, the first chip area 110W_C1 and the second chip area 110W_C2 may be included in different semiconductor chips.

Referring to FIG. 19B, a plurality of trenches TR_120S may be formed to penetrate the wafer substrate 110W. For example, the plurality of trenches TR_120S may be spaced apart from each other in the horizontal direction. The plurality of trenches TR_120S may be formed in the dummy areas 110W_D of the wafer substrate 110W. For example, the plurality of trenches TR_120S may be spaced apart from each other with a portion of the dummy areas 110W_D of the wafer substrate 110W therebetween. Each of the plurality of trenches TR_120S may be formed so that the plurality of chip areas 110W_C of the wafer substrate 110W may be respectively positioned in a space defined by each of the plurality of trenches TR_120S.

In some embodiments, the plurality of trenches TR_120S may be formed through a dry etching process. The plurality of trenches TR_120S may have a horizontal width that decreases as they are closer to the first carrier substrate CR1.

Referring to FIG. 19C, an insulating material is filled in the plurality of trenches TR_120S so that a plurality of protective sidewalls 120S may be formed. The first side 120S_1 of each of the plurality of protective sidewalls 120S may be coplanar with the first side 110W_1 of the wafer substrate 110W, and the second side 120S_2 of each of the plurality of protective sidewalls 120S may be coplanar with the second side 110W_2 of the wafer substrate 110W.

Referring to FIG. 19D, a wafer wiring structure 130W may be disposed on the first side 120S_1 of each of the plurality of protective sidewalls 120S and the first side 110W_1 of the wafer substrate 110W.

The wafer wiring structure 130W may include a plurality of wiring patterns 131W and a wafer wiring insulating layer 132W. The dummy areas 130W_D of the wafer wiring structure 130W in which the plurality of wiring patterns 131W are not positioned, may be disposed on the dummy areas 110W_D of the wafer substrate 110W, and a plurality of wiring areas 130W_W in which the plurality of wiring patterns 131W are positioned, may be disposed on the plurality of chip areas 110W_C of the wafer substrate 110W.

For example, the dummy areas 130W_D of the wafer wiring structure 130W may overlap the dummy areas 110W_D of the wafer substrate 110W and the plurality of protective sidewalls 120S in the vertical direction (Z direction), and the plurality of wiring areas 130W_W of the wafer wiring structure 130W may overlap the plurality of chip areas 110W_C of a wafer substrate 110W in the vertical direction (Z direction).

The plurality of wiring patterns 131W of the wafer wiring structure 130W may be electrically connected to the plurality of chip areas 110W_C of the wafer substrate 110W, respectively. For example, two wiring patterns positioned in different wiring areas 130W_W of the plurality of wiring patterns 131W may not be electrically connected to each other.

For example, the plurality of wiring areas 130W_W of the wafer wiring structure 130W may include a first wiring area 130W_W1 and second wiring patterns 130W_W2 spaced apart from the first wiring area 130W_W1 with the dummy areas 130W_D of the wafer wiring structure 130W therebetween. Wiring patterns positioned in the first wiring area 130W_W1 and wiring patterns positioned in the second wiring area 130W_W2 may not be electrically connected to each other.

For example, the wiring patterns positioned in the first wiring area 130W_W1 of the wafer wiring structure 130W may be electrically connected to the plurality of individual devices positioned in the first chip area 110W_C1 of the first side 110W_1 of the wafer substrate 110W, and the wiring patterns positioned in the second wiring area 130W_W2 of the wafer wiring structure 130W may be electrically connected to the plurality of individual devices positioned in the second chip area 110W_C2 of the first side 110W_1 of the wafer substrate 110W.

Although the operation of forming the plurality of trenches TR_120S and the plurality of protective sidewalls 120S is disclosed as being performed before the operation of forming the wafer wiring structure 130W, the operation of forming the plurality of trenches TR_120S and the plurality of protective sidewalls 120S may be performed after forming the wafer wiring structure 130W. For example, when the plurality of trenches TR_120S and the plurality of protective sidewalls 120S are formed after the wafer wiring structure 130W is formed, the first side 120S_1 of each of the plurality of protective sidewalls 120S may be coplanar with the second side 130W_2 of the wafer wiring structure 130W.

Referring to FIG. 19E, the semiconductor wafer 100W may be cut into a plurality of semiconductor chips 100.

The semiconductor wafer 100W may be cut using the dummy areas 130W_D of the wafer wiring structure 130W and the dummy areas 110W_D of the wafer substrate 110W as scribe lanes. The dummy areas 110W_D of the wafer substrate 110W may be removed so that the wafer substrate 110W may be separated into a plurality of chip substrates 110. The dummy areas 130W_D f the wafer wiring structure 130W may be removed so that the wafer wiring structure 130W may be separated into a plurality of chip wiring structures 130.

The semiconductor wafer 100W may be cut so that the plurality of protective sidewalls 120S may be positioned in the plurality of semiconductor chips 100, respectively. For example, the dummy areas 110W_D of the wafer substrate 110W positioned between the plurality of protective sidewalls 120S may be removed so that the semiconductor wafer 100W may be cut. In the process of dicing the semiconductor wafer 100W, the plurality of protective sidewalls 120S each may not be removed.

A portion of the dummy areas 130W_D of the wafer wiring structure 130W and a portion of the dummy areas 110W_D of the wafer substrate 110W may be removed so that the outer side surface (see 120_OS of FIG. 3) of the plurality of protective sidewalls 120S may not be exposed to the outside.

The semiconductor wafer 100W may be cut so that the wafer substrate 110W and the wafer wiring structure 130W may remain in the outside of each of the plurality of protective sidewalls 120S. In some embodiments, a process of cutting the semiconductor wafer 100W may be performed with at least one of a laser dicing process, a mechanical dicing process, and a plasma dicing process.

Referring to FIGS. 19F and 19G, an etching process may be performed on the result of FIG. 19E so that the outer side surface (see 120_OS of FIG. 3) of each of the plurality of protective sidewalls 120S may be exposed to the outside.

For example, wet etching may be performed on the result of FIG. 19E so that a portion of the wafer substrate 110W that remains in the outside of each of the plurality of protective sidewalls 120S may be removed. For example, the wafer substrate 110W may be etched as a main target using etching materials having different etching ratios for the plurality of protective sidewalls 120S and the wafer substrate 110W.

In some embodiments, in the process of removing the wafer substrate 110W positioned in the outside of each of the plurality of protective sidewalls 120S, the portion of the chip wiring structure 130 positioned in the outside of each of the plurality of protective sidewalls 120S may be partially etched. Thus, the corner of the first side 130_1 of the chip wiring structure 130 may be rounded.

Only a portion of the wiring insulating layer 132 of the chip wiring structure 130 may be etched in an etching process, so that the chip wiring structure 130 may be positioned on the outside of the protective sidewalls 120S. For example, there may be a step height between chip wiring structure 130 and the protective sidewalls 120S. For example, the width of the chip wiring structure 130 may be greater than a separation distance between the first outer side surface (see 120_OS1 of FIG. 3) of the protective sidewalls 120S and the second outer side surface (see 120_OS2 of FIG. 3) of the protective sidewalls 120S.

Through an etching process to be performed after the dicing process, the roughness of an outer surface of the semiconductor chip 100 may be lowered, and cracks may be removed. Thus, a warpage phenomenon in which the semiconductor chip 100 bends, may be suppressed, and the phenomenon in which voids are generated when the semiconductor chip 100 is mounted in an external device, may be suppressed.

Subsequently, each of the plurality of semiconductor chips 100 may be separated from the first carrier substrate CR1.

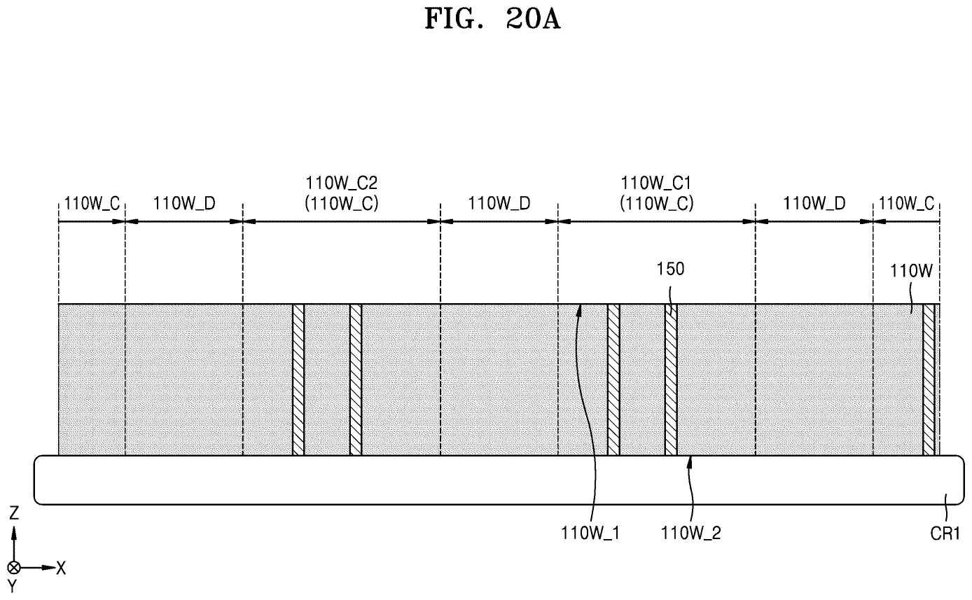

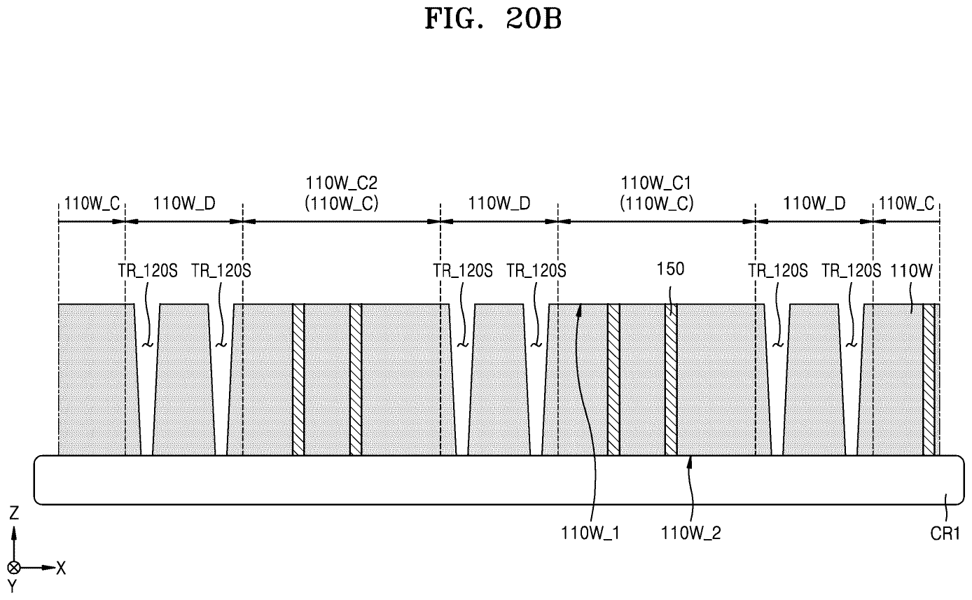

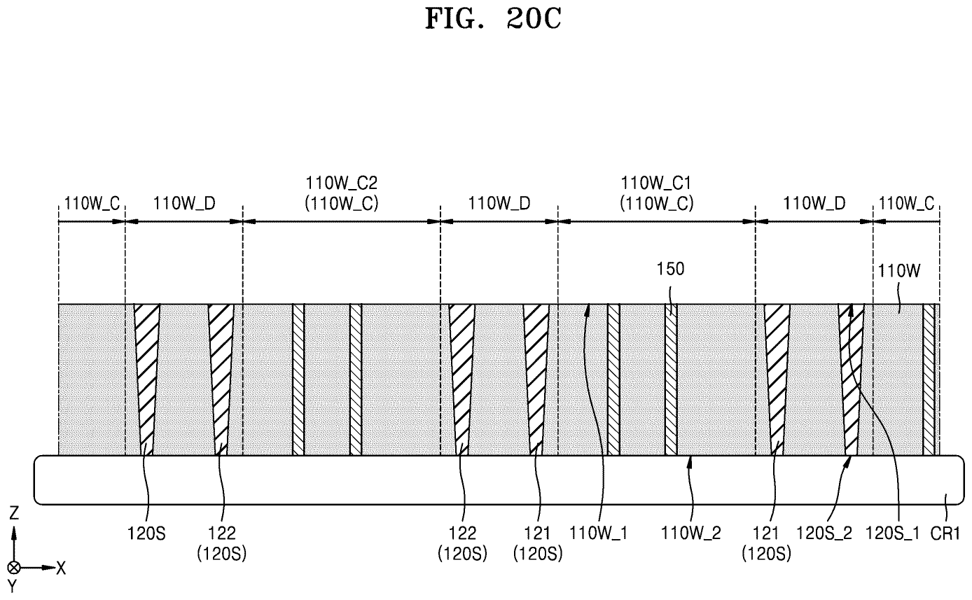

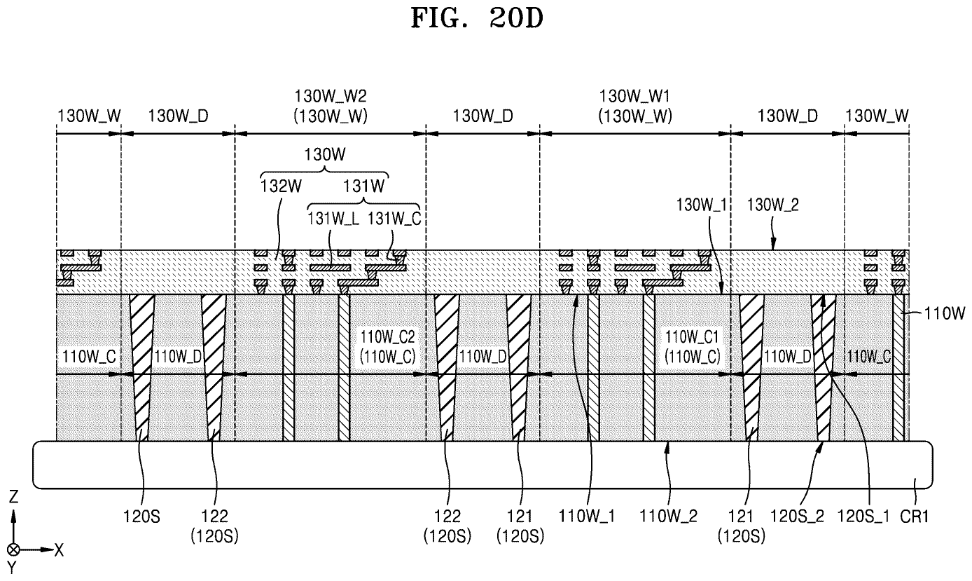

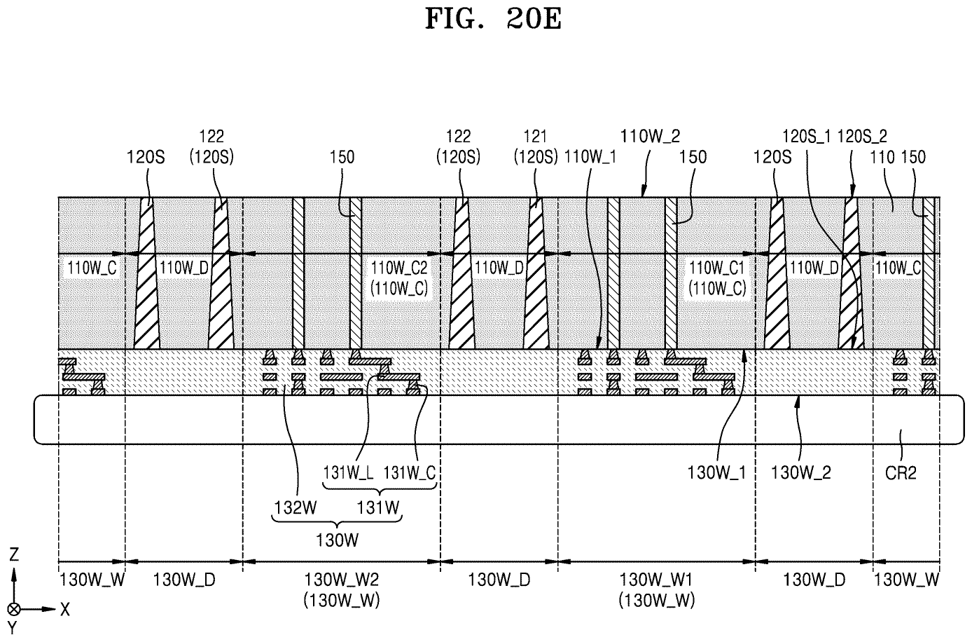

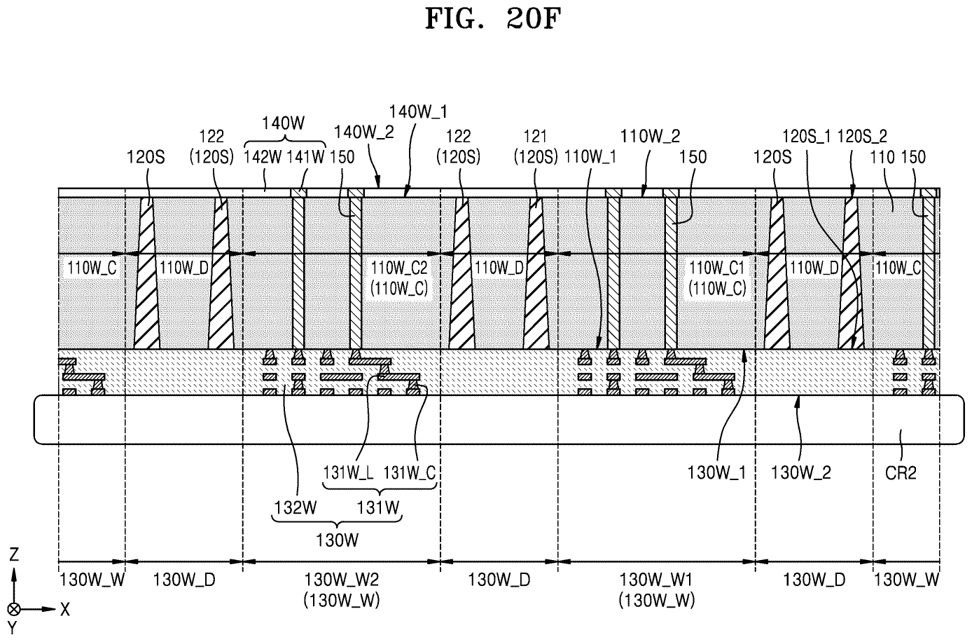

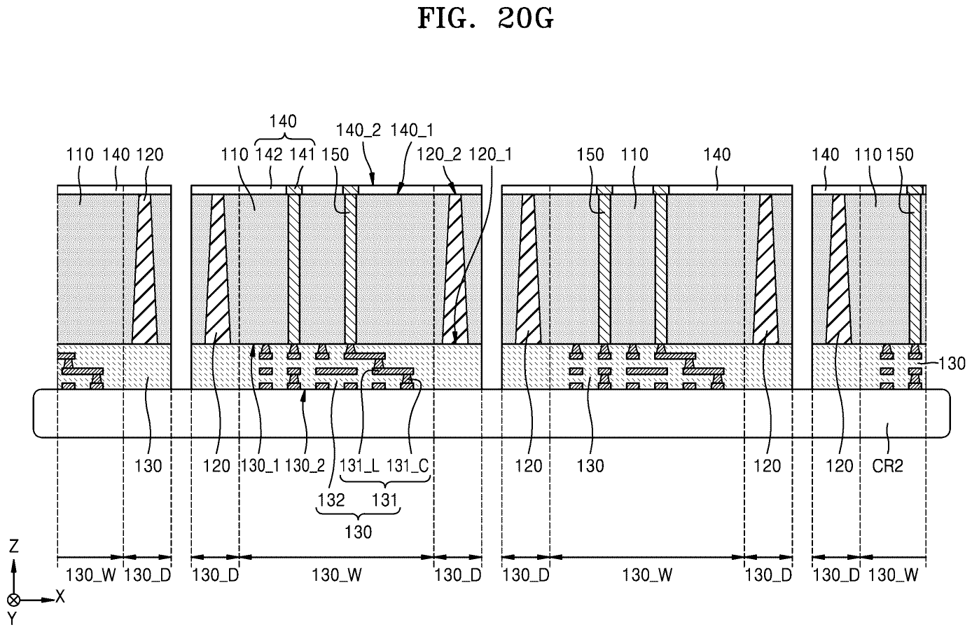

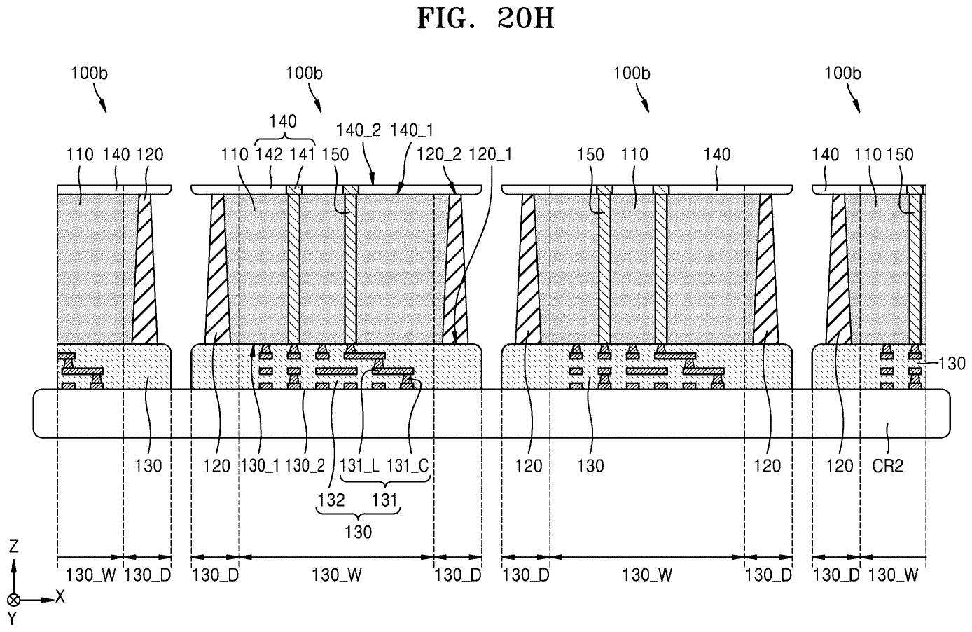

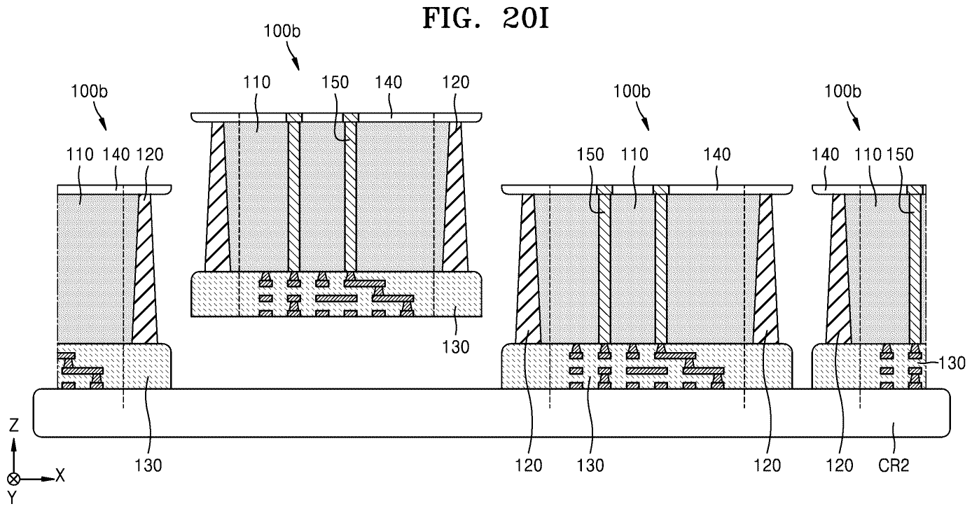

FIGS. 20A through 20I are cross-sectional views illustrating a method of manufacturing a semiconductor chip according to embodiments in a process sequence. Specifically, FIGS. 20A through 20F illustrate an operation of manufacturing the semiconductor wafer 100Wb shown in FIG. 13 in a process sequence. FIGS. 20G through 20I illustrate an operation of cutting the semiconductor wafer 100Wb to separate the semiconductor wafer 100Wb into the semiconductor chips 100b shown in FIG. 6 in a process sequence.

Referring to FIG. 20A, the wafer substrate 110W in which the through via 150 is formed, may be mounted on the first carrier substrate CR1. In some embodiments, the wafer substrate 110W may be mounted on the first carrier substrate CR1 through an adhesive film.

The wafer substrate 110W may have a disc shape and may include a first side 110W_1 and a second side 110W_2 opposite thereto. The first side 110W_1 of the wafer substrate 110W may be a side on which a plurality of individual devices are positioned, and the second side 110W_2 of the wafer substrate 110W may face the first carrier substrate CR1.

For example, the wafer substrate 110W may be classified into a plurality of chip areas 110W_C and dummy areas 110W_D for defining the plurality of chip areas 110W_C. The plurality of chip areas 110W_C may be arranged in a matrix shape. Each of the plurality of chip areas 110W_C of the wafer substrate 110W may be an area separated into the semiconductor chips 100 later.

The through via 150 may be positioned in the plurality of chip areas 110W_C of the wafer substrate 110W. For example, the through via 150 may extend from the first side 110W_1 of the wafer substrate 110W to the second side 110W_2 of the wafer substrate 110W in the vertical direction (Z direction).

Referring to FIG. 20B, the plurality of trenches TR_120S may be formed to penetrate the wafer substrate 110W. For example, the plurality of trenches TR_120S may be spaced apart from each other in the horizontal direction. The plurality of trenches TR_120S may be formed in the dummy areas 110W_D of the wafer substrate 110W. For example, the plurality of trenches TR_120S may be spaced apart from each other with a portion of the dummy areas 110W_D of the wafer substrate 110W therebetween. Each of the plurality of trenches TR_120S may be formed so that the plurality of chip areas 110W_C of the wafer substrate 110W may be respectively positioned in a space defined by each of the plurality of trenches TR_120S.

In some embodiments, the plurality of trenches TR_120S may be formed through a dry etching process. The plurality of trenches TR_120S may have a horizontal width that decreases as they are closer to the first carrier substrate CR1.

Referring to FIG. 20C, an insulating material may be filled in the plurality of trenches TR_120S so that the plurality of protective sidewalls 120S may be formed. The first side 120S_1 of each of the plurality of protective sidewalls 120S may be coplanar with the first side 110W_1 of the wafer substrate 110W, and the second side 120S_2 of each of the plurality of protective sidewalls 120S may be coplanar with the second side 110W_2 of the wafer substrate 110W.

Referring to FIG. 20D, the wafer wiring structure 130W may be disposed on the first side 120S_1 of each of the plurality of protective sidewalls 120S and the first side 110W_1 of the wafer substrate 110W. The wafer wiring structure 130W may be electrically connected to the through via 150.

The wafer wiring structure 130W may include a plurality of wiring patterns 131W and a wafer wiring insulating layer 132W. The wafer wiring structure 130W may include the plurality of wiring areas 130W_W in which the plurality of wiring patterns 131W are positioned, and the dummy areas 130W_D for defining the plurality of wiring areas 130W_W.

For example, the dummy areas 130W_D of the wafer wiring structure 130W may overlap the dummy areas 110W_D of the wafer substrate 110W and the plurality of protective sidewalls 120S in the vertical direction (Z direction), and the plurality of wiring areas 130W_W of the wafer wiring structure 130W may overlap the plurality of chip areas 110W_C of a wafer substrate 110W in the vertical direction (Z direction).

The plurality of wiring patterns 131W of the wafer wiring structure 130W each may be electrically connected to the plurality of chip areas 110W_C of the wafer substrate 110W, respectively. For example, two wiring patterns positioned in different wiring areas 130W_W of the plurality of wiring patterns 131W may not be electrically connected to each other.

For example, the plurality of wiring areas 130W_W of the wafer wiring structure 130W may include a first wiring area 130W_W1 and second wiring patterns 130W_W2 spaced apart from the first wiring area 130W_W1 with the dummy areas 130W_D of the wafer wiring structure 130W therebetween. Wiring patterns positioned in the first wiring area 130W_W1 and wiring patterns positioned in the second wiring area 130W_W2 may not be electrically connected to each other.

For example, the wiring patterns positioned in the first wiring area 130W_W1 of the wafer wiring structure 130W may be electrically connected to the plurality of individual devices positioned in the first chip area 110W_C1 of the first side 110W_1 of the wafer substrate 110W, and the through via 150 positioned in the first chip area 110W_C1 of the wafer substrate 110W. Wiring patterns positioned in the second wiring area 130W_W2 of the wafer wiring structure 130W may be electrically connected to the plurality of individual devices positioned in the second chip area 110W_C2 of the first side 110W_1 of the wafer substrate 110W and the through via 150 positioned in the second chip area 110W_C2 of the wafer substrate 110W.

Referring to FIGS. 20E and 20F, a wafer bonding structure 140W may be disposed on the second side 120S_2 of each of the plurality of sidewalls 120S and the second side 110W_2 of the wafer substrate 110W.

The result of FIG. 20D may be separated from the first carrier substrate CR1 and thus may be moved to the second carrier substrate CR2. The result of FIG. 20D may be flipped so that the wafer wiring structure 130W may be positioned on the second carrier substrate CR2 and the second side 110W_2 of the wafer substrate 110W may be spaced apart from the second carrier substrate CR2.

After the wafer substrate 110W and the wafer wiring structure 130W are moved to the second carrier substrate CR2, the wafer bonding structure 140W may be disposed on the wafer substrate 110W.

The wafer bonding structure 140W may include a plurality of bonding patterns 141W and a wafer bonding insulating layer 142W that surrounds the plurality of bonding patterns 141W. Each of the plurality of bonding patterns 141W may overlap each of the plurality of chip areas 110W_C of the wafer substrate 110W in the vertical direction (Z direction) and may be electrically connected to the through via 150 positioned inside each of the plurality of chip areas 110W_C.

In some embodiments, the wafer bonding structure 140W may include a plurality of pattern areas in which a plurality of bonding patterns are positioned, and dummy areas for defining the plurality of pattern areas. The plurality of pattern areas of the wafer bonding structure 140W may overlap the plurality of chip areas 110W_C of the wafer substrate 110W in the vertical direction (Z direction), and the dummy areas of the wafer bonding structure 140W may overlap the dummy areas 110W_D of the wafer substrate 110W in the vertical direction (Z direction).

The dummy areas of the wafer bonding structure 140W may cover the plurality of protective sidewalls 120S. For example, the dummy areas of the wafer bonding structure 140W and the plurality of protective sidewalls 120S may overlap each other in the vertical direction (Z direction).

Although the operation of forming the plurality of trenches TR_120S and the plurality of protective sidewalls 120S is disclosed as being performed before the operation of forming the wafer wiring structure 130W, the operation of forming the plurality of trenches TR_120S and the plurality of protective sidewalls 120S may be performed after forming the wafer wiring structure 130W or after forming the wafer bonding structure 140W.

For example, when the plurality of trenches TR_120S and the plurality of protective sidewalls 120S are formed after the wafer wiring structure 130W is formed, the first side 120S_1 of each of the plurality of protective sidewalls 120S may be coplanar with the second side 130W_2 of the wafer wiring structure 130W.

For example, when the plurality of trenches TR_120S and the plurality of protective sidewalls 120S are formed after the wafer bonding structure 140W is formed, the second side 120S_2 of each of the plurality of protective sidewalls 120S may be coplanar with the first side 140W_1 of the wafer wiring structure 130W.

For example, when the plurality of trenches TR_120S and the plurality of protective sidewalls 120S are formed after the wafer bonding structure 140W is formed, the horizontal width of each of the plurality of protective sidewalls 120S may decrease as they are closer to the wafer wiring structure 130W.

Referring to FIG. 20G, the semiconductor wafer 100Wb may be cut into a plurality of semiconductor chips 100b.

The semiconductor wafer 100Wb may be cut using the dummy areas of the wafer bonding structure 140W, the dummy areas 130W_D of the wafer wiring structure 130W, and the dummy areas 110W_D of the wafer substrate 110W as scribe lanes.

The dummy areas 110W_D of the wafer substrate 110W may be removed so that the wafer substrate 110W may be separated into a plurality of chip substrates 110. The dummy areas 130W_D f the wafer wiring structure 130W may be removed so that the wafer wiring structure 130W may be separated into a plurality of chip wiring structures 130. The dummy areas of the wafer bonding structure 140W may be removed so that the wafer bonding structure 140W may be separated into a plurality of bonding structures 140.

The semiconductor wafer 100Wb may be cut so that the plurality of protective sidewalls 120S may be positioned in the plurality of semiconductor chips 100b, respectively. For example, the dummy areas 110W_D of the wafer substrate 110W positioned between the plurality of protective sidewalls 120S may be removed so that the semiconductor wafer 100Wb may be cut. In the process of diving the semiconductor wafer 100Wb, the plurality of protective sidewalls 120S may not be respectively removed.

A portion of the dummy areas of the wafer bonding structure 140W, a portion of the dummy areas of the wafer wiring structure 130W, and a portion of the dummy areas 110W_D of the wafer substrate 110W may be removed so that the outer side surface (see 120_OS of FIG. 3) of the plurality of protective sidewalls 120S may not be exposed to the outside.

The semiconductor wafer 100Wb may be cut so that the wafer substrate 110W, the wafer wiring structure 130W and the wafer bonding structure 140W may remain in the outside of each of the plurality of protective sidewalls 120S. In some embodiments, the process of cutting the semiconductor wafer 100Wb may be performed with at least one of a laser dicing process, a mechanical dicing process, and a plasma dicing process.

Referring to FIGS. 20H and 20I, an etching process may be performed on the result of FIG. 20G so that the outer side surface (see 120_OS of FIG. 3) of each of the plurality of protective sidewalls 120S may be exposed to the outside.

For example, wet etching may be performed on the result of FIG. 20G so that a portion of the wafer substrate 110W that remains in the outside of each of the plurality of protective sidewalls 120S may be removed. For example, the wafer substrate 110W may be etched as a main target using etching materials having different etching ratios for the multiple protective sidewalls 120S and the wafer substrate 110W.

In some embodiments, in the process of removing the wafer substrate 110W positioned on the outside of each of the plurality of protective sidewalls 120S, the portion of the chip wiring structure 130 positioned on the outside of each of the plurality of protective sidewalls 120S may be partially etched. Thus, the corner of the first side 130_1 of the chip wiring structure 130 may be rounded.

Only a portion of the wiring insulating layer 132 of the chip wiring structure 130 may be etched in an etching process so that the chip wiring structure 130 may be positioned in the outside of the protective sidewalls 120. For example, there may be a step height between the chip wiring structure 130 and the protective sidewalls 120. For example, the width of the chip wiring structure 130 may be greater than a separation distance between the first outer side surface (see 120_OS1 of FIG. 3) of the protective sidewalls 120 and the second outer side surface (see 120_OS2 of FIG. 3) of the protective sidewalls 120.

In some embodiments, in the process of removing the wafer substrate 110W positioned on the outside of each of the plurality of protective sidewalls 120S, a portion of the bonding structure 140 positioned on the wafer substrate 110W positioned on the outside of each of the plurality of protective sidewalls 120S may be partially etched. Thus, the corner of the first side 140_1 of the bonding structure 140 may be rounded.

Only a portion of the bonding insulating layer 142 of the bonding structure 140 may be etched in the etching process so that the bonding structure 140 may be positioned on the outside the protective sidewalls 120. For example, there may be a step height between the bonding structure 140 and the protective sidewalls 120. For example, the width of the bonding structure 140 may be greater than a separation distance between the first outer side surface (see 120_OS1 of FIG. 3) of the protective sidewalls 120 and the second outer side surface (see 120_OS2 of FIG. 3) of the protective sidewalls 120.

Through an etching process to be performed after the dicing process, the roughness of the outer surface of the semiconductor chip 100b may be lowered, and cracks may be removed. Thus, the warpage phenomenon in which the semiconductor chip 100b bends, may be suppressed, and the phenomenon in which voids are generated when the semiconductor chip 100b is mounted in an external device, may be suppressed.

Subsequently, the plurality of semiconductor chips 100b may be respectively separated from the first carrier substrate CR1.

While the inventive concept has been particularly shown and described with reference to embodiments thereof, it will be understood that various changes in form and details may be made therein without departing from the spirit and scope of the following claims.

What is claimed is:

1. A semiconductor chip comprising:
a chip substrate comprising a first side and a second side opposing the first side in a vertical direction;
a chip wiring structure positioned on the first side of the chip substrate and comprising a wiring area and dummy areas surrounding the wiring area; and
a protective sidewall overlapping the dummy areas of the chip wiring structure in the vertical direction, being in contact with a side surface of the chip substrate and having an inner side surface coplanar with the side surface of the chip substrate,
wherein the chip wiring structure comprises wiring patterns positioned in the wiring area and electrically connected to the chip substrate, and a wiring insulating layer positioned in the wiring area and the dummy areas and surrounding the wiring patterns, and
the wiring insulating layer of the chip wiring structure extends to an outside of the protective sidewall.

2. The semiconductor chip of claim 1, wherein
the protective sidewall comprises an outer side surface opposing the inner side surface, and
the outer side surface of the protective sidewall comprises a first outer side surface and a second outer side surface that are spaced apart from each other with the chip substrate therebetween, and
a separation distance between the first outer side surface and the second outer side surface is less than a width of the chip wiring structure.

3. The semiconductor chip of claim 1, wherein
a first side of the chip wiring structure is in contact with the first side of the chip substrate, and
a corner of the first side of the chip wiring structure is rounded.

4. The semiconductor chip of claim 1, wherein
the protective sidewall comprises a first side and a second side adjacent to the inner side surface, and
the first side of the protective sidewall is coplanar with the first side of the chip substrate and is in contact with the chip wiring structure, and
the second side of the protective sidewall is coplanar with the second side of the chip substrate.

5. The semiconductor chip of claim 4, wherein
the protective sidewall comprises an outer side surface opposing the inner side surface and being adjacent to the first side and the second side of the protective sidewall, and
in a plan view, the outer side surface of the protective sidewall is spaced apart from a side surface of the chip wiring structure and is positioned on a first side of the chip wiring structure that is in contact with the chip substrate.

6. The semiconductor chip of claim 1, wherein
the protective sidewall comprises an outer side surface opposing the inner side surface, and a first side and a second side being adjacent to the inner side surface and the outer side surface, and
the chip wiring structure comprises a first side being in contact with the chip substrate and a second side opposing the first side of the chip wiring structure, and
the protective sidewall penetrates the chip wiring structure, and
the first side of the protective sidewall and the second side of the chip wiring structure are coplanar with each other, and
the second side of the protective sidewall and the second side of the chip substrate are coplanar with each other, and
a portion of the outer side surface of the protective sidewall is covered by the wiring insulating layer of the chip wiring structure.

7. The semiconductor chip of claim 1, further comprising:
a through via penetrating the chip substrate and being electrically connected to the chip wiring structure; and
a bonding structure positioned on the second side of the chip substrate and comprising bonding patterns being electrically connected to the through via and a bonding insulating layer surrounding the bonding patterns,
wherein the bonding structure comprises a pattern area and dummy areas surrounding the pattern area, and
the bonding insulating layer of the bonding structure extends to an outside of the protective sidewall, and
the protective sidewall overlaps the dummy areas of the bonding structure in the vertical direction.

8. The semiconductor chip of claim 7, wherein
the protective sidewall comprises an outer side surface opposing the inner side surface, and
the outer side surface of the protective sidewall comprises a first outer side surface and a second outer side surface that are spaced apart from each other with the chip substrate therebetween, and
a separation distance between the first outer side surface and the second outer side surface is less than a width of the bonding structure.

9. The semiconductor chip of claim 8, wherein
the chip wiring structure comprises a first side being in contact with the chip substrate and a second side opposing the first side of the chip wiring structure, and
the protective sidewall penetrates the chip wiring structure, and
the first side of the protective sidewall and the first side of the chip wiring structure are coplanar with each other, and
a portion of the outer side surface of the protective sidewall is covered by the wiring insulating layer of the chip wiring structure.

10. The semiconductor chip of claim 7, wherein
the protective sidewall comprises an outer side surface opposing the inner side surface, and a first side and a second side being adjacent to the inner side surface and the outer side surface, and
the bonding structure comprises a first side being in contact with the chip substrate and a second side opposing the first side of the bonding structure, and
the protective sidewall penetrates the chip wiring structure, and
the first side of the protective sidewall and the second side of the bonding structure are coplanar with each other, and
a portion of the outer side surface of the protective sidewall is covered by the wiring insulating layer of the chip wiring structure.

11. The semiconductor chip of claim 1, wherein the protective sidewall has a horizontal width that varies in a direction away from the chip wiring structure.

12. The semiconductor chip of claim 1, wherein the protective sidewall comprises a silicon oxide.

13. A semiconductor wafer comprising:
a wafer substrate comprising a first side and a second side opposing the first side, and comprising a plurality of chip areas being spaced apart from each other and dummy areas defining the plurality of chip areas;
a wafer wiring structure positioned on the first side of the wafer substrate, and comprising a plurality of wiring areas overlapping the plurality of chip areas of the wafer substrate in a vertical direction and dummy areas overlapping the dummy areas of the wafer substrate in the vertical direction; and
a plurality of protective sidewalls penetrating the wafer substrate and positioned in the dummy areas of the wafer substrate, wherein the plurality of chip areas are respectively positioned in a space surrounded by each of the plurality of protective sidewalls.

14. The semiconductor wafer of claim 13, wherein
a portion of the dummy areas of the wafer substrate is positioned in a separation space between the plurality of protective sidewalls, and
a portion of the dummy areas of the wafer wiring structure is positioned on the wafer substrate positioned in the separation space between the plurality of protective sidewalls.

15. The semiconductor wafer of claim 13, further comprising;
a through via penetrating the chip areas of the wafer substrate in the vertical direction and being electrically connected to the wafer wiring structure; and
a wafer bonding structure positioned on the second side of the wafer substrate, and comprising a plurality of pattern areas overlapping the plurality of chip areas of the wafer substrate in the vertical direction and dummy areas overlapping the dummy areas of the wafer substrate in the vertical direction,
wherein the through via is electrically connected to the wafer bonding structure.

16. The semiconductor wafer of claim 13, wherein a height of each of the plurality of protective sidewalls is greater than or equal to a height of the wafer substrate.

17. A semiconductor package comprising:
a package substrate;
a semiconductor chip comprising:
a chip substrate including a first side and a second side opposing the first side in a vertical direction;
a chip wiring structure positioned on the first side of the chip substrate and including wiring areas and dummy areas surrounding the wiring areas; and
a protective sidewall overlapping the dummy areas of the chip wiring structure in the vertical direction, being in contact with a side surface of the chip substrate and having an inner side surface coplanar with the side surface of the chip substrate,
wherein, in the semiconductor chip, the chip wiring structure is positioned on the package substrate; and
a molding layer positioned on the package substrate and covering an outer side surface of the protective sidewall of the semiconductor chip,
wherein the outer side surface of the protective sidewall of the semiconductor chip comprises a first outer side surface and a second outer side surface that are spaced apart from each other with the chip substrate therebetween, and
a separation distance between the first outer side surface and the second outer side surface of the protective sidewall of the semiconductor chip is less than a width of the chip wiring structure.

18. The semiconductor package of claim 17, wherein
the chip wiring structure of the semiconductor chip extends to an outside of the protective sidewall of the semiconductor chip.

19. The semiconductor package of claim 17, wherein
the semiconductor chip further comprises: a through via penetrating the chip substrate and being electrically connected to the chip wiring structure, bonding patterns positioned on the second side of the chip substrate and being electrically connected to the through via, and a bonding insulating layer surrounding the bonding patterns; and
a stack semiconductor chip stacked on the bonding structure of the semiconductor chip.

20. The semiconductor package of claim 17, further comprising
a subsidiary layer disposed between the package substrate and the molding layer and between the semiconductor chip and the molding layer.
